(19) United States
(12) Patent Application Publication
(10) Pub. No.: US 2026/0353823 A1
(43) Pub. Date: Nov. 5, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Ming-Chieh HSU, Hsinchu City (TW); Shyh-Fann TING, Tainan City (TW); Tzu-Jui WANG, Hsinchu County (TW); Shih-Min HUANG, Hsinchu County (TW); Hung-Chang CHIEN, Hsinchu County (TW)

(21) Appl. No.: 19/197,666

(22) Filed: May 2, 2025

(51) Int. Cl. H10F 39/00; H10F 30/225; H10F 39/18

(52) U.S. Cl. CPC H10F 39/014; H10F 39/028; H10F 39/811; H10F 30/225; H10F 39/18

(57) ABSTRACT

Etch stop layers (ESLs) are formed on an absorption layer and on doped regions of a single-photon avalanche diode before etching contact structure recesses. The etch rate for the ESLs is slower than etch rates for other materials in which the recesses will be formed so that one contact mask and one etch process can be used to form shallow and deep contact structures. The ESLs reduce the etch rate when forming recesses with smaller vertical dimensions in comparison to the etch rate when forming recesses with larger vertical dimensions. As a result, the etching of contact structure recesses with larger and smaller vertical dimensions may be performed in the same etch operation. The process prevents unwanted residue that may be formed on dielectric layers and/or in recesses from multiple masks. As a result, device performance and/or reliability may be increased.

### BACKGROUND

Complementary metal oxide semiconductor (CMOS) image sensors utilize light-sensitive CMOS circuitry to convert light energy (e.g., photons) into electrical energy. The light-sensitive CMOS circuitry may include a photodiode formed in a silicon substrate. As the photodiode is exposed to light, an electrical charge is induced in the photodiode (referred to as a photocurrent). The photodiode may be coupled to a transfer gate, which is used to sample the charge of the photodiode. Colors may be determined by placing filters over the light-sensitive CMOS circuitry.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example semiconductor device described herein.

FIG. 2 is a diagram of an example implementation of a photodetector structure that may be included in a semiconductor device described herein.

FIG. 3 is a diagram of an example implementation of a photodetector structure that may be included in a semiconductor device described herein.

FIGS. 4A-4L are diagrams of an example implementation of forming a photodetector structure described herein.

FIGS. 5A-5Q are diagrams of an example implementation of forming a photodetector structure described herein.

FIG. 6 is a flowchart of an example process associated with forming a semiconductor device described herein.

FIG. 7 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An avalanche photodiode operating in a so-called Geiger mode, referred to as a single-photon avalanche diode (SPAD), is a highly sensitive photodetector capable of outputting a trigger signal upon detection of an ultralow-power signal, down to the single photon level. A SPAD can be used in, for example, a mobile front-end image sensor for light source detection or light detection and ranging (LIDAR) in an automotive system, among other examples.

A SPAD image sensor includes an array of SPADs on a substrate. In operation, a given SPAD produces an output pulse when struck by a photon. Generally, the SPAD has a p-n junction that is reverse biased above a breakdown voltage such that a single-photon-generated carrier can trigger an avalanche multiplication process that causes current at an output of a photon detection cell to rapidly reach a final value. This avalanche current continues until a quenching element quenches the avalanche process by reducing the bias voltage. An intensity of the photon signal received by the SPAD is obtained by counting a number of these output pulses within a window of time.

In some cases, SPADs may include shallow and deep contact structures for device connections, and the depth difference may be large between the shallow and deep contact structures. As a result, forming the shallow and deep contact structures may require separate etch processes that use different photoresists and/or masks to form the recesses for the contact structures. Multiple etch processes may leave unwanted photoresist residue on dielectric layers and/or in recesses after photoresist removal, which may decrease device performance and/or reliability. In addition, there may be difficulties aligning a metallization layer with the shallow and deep contact structures.

In some implementations described herein, etch stop layers (ESLs) are formed on an absorption layer and on doped regions of a SPAD before recesses are etched for contact structures that are to be formed over the absorption layer and the doped regions. The etch rate for the ESLs is slower than etch rates for other materials in which the recesses will be formed, so that one contact mask and one etch process can be used to form shallow and deep contact structures. In more detail, the ESLs reduce the etch rate when forming recesses with smaller vertical dimensions, in comparison to the etch rate when forming recesses with larger vertical dimensions. As a result, the etching of contact structure recesses with larger and smaller vertical dimensions may be performed in the same etch operation, where the etching of the recesses with the different vertical dimensions is completed at the same or approximately the same time. Thicknesses of the ESLs may be controlled so that etching of recesses having the different vertical dimensions is simultaneously completed. The use of a single mask (e.g., photoresist) in an etch operation to form contact structure recesses with the different vertical dimensions prevents unwanted residue that may be formed on dielectric layers and/or in recesses from multiple masks. As a result, device performance and/or reliability may be increased. In addition, difficulties in aligning a metallization layer with shallow and deep contact structures that may be encountered when multiple recess etch operations are performed may be avoided.

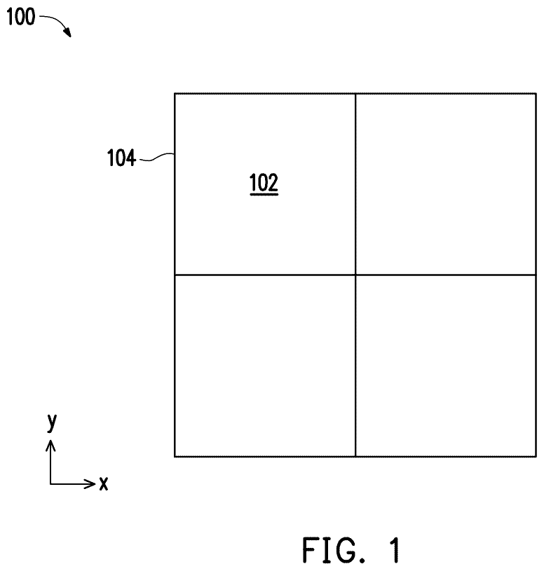

FIG. 1 is a diagram of an example semiconductor device 100 described herein. FIG. 1 illustrates a top view of the semiconductor device 100 (or a portion thereof). The semiconductor device 100 may include an image sensor device, an automotive sensor (e.g., a LIDAR sensor), an infrared detector, a time of flight (ToF) sensor, and/or another semiconductor device that includes one or more photodetector structures 102.

As shown in FIG. 1, the photodetector structures 102 may be arranged in a grid in the semiconductor device 100. However, other arrangements and quantities of photodetector structures 102 are within the scope of the present disclosure. The photodetector structures 102 may be configured to generate an electrical signal (e.g., a photocurrent) by converting photons of incident light to electrons through the photoelectric effect.

An isolation structure 104 (e.g., a deep trench isolation (DTI) structure, a shallow trench isolation (STI) structure) may be included around the photodetector structures 102 to reduce optical crosstalk between the photodetector structures 102. The isolation structure 104 may include a plurality of interconnected segments that laterally surround the photodetector structures 102.

As indicated above, FIG. 1 is provided as an example. Other examples may differ from what is described with regard to FIG. 1.

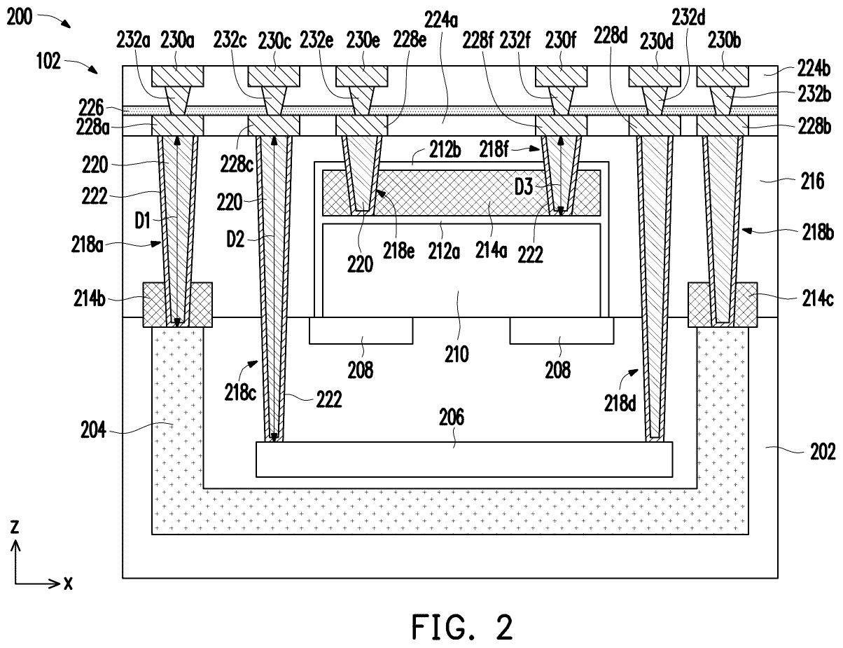

FIG. 2 is a diagram of an example implementation 200 of a photodetector structure 102 that may be included in a semiconductor device 100 described herein. The photodetector structure 102 may be a SPAD structure. As shown in FIG. 2, the photodetector structure 102 includes, or may be included in, a semiconductor layer 202 (e.g., a substrate). The semiconductor layer 202 may correspond to a substrate layer of the semiconductor device 100. Alternatively, the semiconductor layer 202 may correspond to a top semiconductor layer of a silicon-on-insulator (SOI) substrate on which the semiconductor device 100 was formed. The semiconductor layer 202 may include a semiconductor material such as silicon (Si), undoped silicon, silicon doped with p-type dopants (e.g., boron (B) and/or gallium (Ga), among other examples), silicon doped with n-type dopants (e.g., arsenic (As) and/or phosphorous (P), among other examples), and/or another semiconductor material.

The semiconductor layer 202 may include various doping configurations to satisfy one or more design parameters. For example, different doping profiles (e.g., n-wells, p-wells) may be formed in the semiconductor layer 202. The doping may be performed by ion implantation of dopants and/or diffusion processes. The photodetector structure 102 may include a plurality of doped regions that are included in the semiconductor layer 202. For example, the photodetector structure 102 may include a p-doped region 204, an n-doped region 206, and p-doped regions 208 in the semiconductor layer 202. The p-doped region 204 and the p-doped regions 208 may be regions of the semiconductor layer 202 that are doped with one or more p-type dopants, such as boron (B), gallium (Ga), and/or indium (In), among other examples. The n-doped region 206 may be a region of the semiconductor layer 202 that is doped with one or more n-type dopants, such as phosphorous (P), arsenic (As), bismuth (Bi), and/or antimony (Sb), among other examples. The p-doped region 204 is formed in a U-shape around the n-doped region 206. The p-doped region 204 is formed on lateral sides of and under the n-doped region 206.

The photodetector structure 102 includes a photon absorption region 210 (e.g., absorption layer) on the semiconductor layer 202, and on the p-doped regions 208. The photon absorption region 210 is in physical contact with p-doped regions 208. The photon absorption region 210 may be configured to absorb photons of incident light and convert the photons to electrons through the photoelectric effect. A SPAD may be biased at fields greater than an avalanche breakdown so that avalanche breakdown may be used to detect individual photons. In other words, an avalanche current may be triggered by a single photon incident on the photon absorption region 210. In some implementations, the p-doped regions 208 function as charge sheets to control an electric field so that the electric field is high enough in a region (e.g., collection region) between the photon absorption region 210 and the n-doped region 206 to permit avalanche breakdown to be reached, and low enough in the photon absorption region 210 to prevent tunneling.

The photons interact with electron-hole pairs in the photon absorption region 210. The interaction causes electrons and holes to be separated and to migrate toward the collection region between the photon absorption region 210 and the n-doped region 206 in the semiconductor layer 202, resulting in the generation of an electric field (e.g., a built-in electric field). The accumulation of holes and the accumulation of electrons at the collection region cause a photocurrent to be generated. The magnitude of the photocurrent may be proportional to the amount of photons that is collected in the photon absorption region 210. Accordingly, the photocurrent that is generated may be an indication of the intensity of the incident light.

The photon absorption region 210 may include a semiconductor material. The semiconductor material of the photon absorption region 210 may be the same as the semiconductor material of the semiconductor layer 202. Additionally and/or alternatively, the semiconductor material of the photon absorption region 210 and the semiconductor material of the semiconductor layer 202 may be different semiconductor materials. Examples of semiconductor materials for the photon absorption region 210 include germanium (Ge), germanium tin (GeSn), silicon germanium (SiGe), indium gallium arsenide (InGaAs), and/or gallium arsenide (GaAs), among other examples.

In some implementations, a first buffer layer 212a is disposed on a top surface of the photon absorption region 210, and a first ESL 214a is disposed on the first buffer layer 212a. A second buffer layer 212b is disposed on a top surface of the first ESL 214a, and on sides of a stacked arrangement in the z-direction of the photon absorption region 210, the first buffer layer 212a on the photon absorption region 210, and the first ESL 214a on the first buffer layer 212a. A second ESL 214b and a third ESL 214c are disposed on top surfaces of the p-doped region 204 on opposite lateral sides of the photodetector structure 102 in the x-direction. In some implementations, the first and second buffer layers 212a and 212b include a semiconductor material such as silicon (Si), and the ESLs 214a-214c may include a silicon nitride (SiₓN_{y}), silicon carbide (SiC), silicon oxynitride (SiON), and/or another suitable dielectric material. The first ESL 214a may be in physical contact with the first buffer layer 212a, and the second and third ESLs 214b and 214c may be in physical contact with the top surfaces of the p-doped region 204. In some implementations, the second and third ESLs 214b and 214c are partially recessed in the semiconductor layer 202. Alternatively, bottom surfaces of the second and third ESLs 214b and 214c are coplanar or approximately coplanar with a top surface of the semiconductor layer 202.

A dielectric layer 216 is disposed on the semiconductor layer 202. The dielectric layer 216 is further disposed on and around sides of the stacked arrangement of the photon absorption region 210, the first buffer layer 212a on the photon absorption region 210, the first ESL 214a on the first buffer layer 212a, and the second buffer layer 212b on the first ESL 214a. The dielectric layer 216 is further disposed on and around sides of the second and third ESLs 214b and 214c. The dielectric layer 216 may include a low dielectric constant (low-k) oxide material such as silicon oxide (SiOₓ) or undoped silicate glass (USG). Additionally and/or alternatively, the dielectric layer 216 may include a boron-containing silicate glass (BSG), a fluorine-containing silicate glass (FSG), tetraethyl orthosilicate (TEOS), hydrogen silsesquioxane (HSQ), and/or another suitable dielectric material. In some implementations, the dielectric layer 216 includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (α-CₓF_{y}), parylene, bis-benzocyclobutenes (BCB), polytetrafluoroethylene (PTFE), a silicon oxycarbide (SiOC) polymer, porous HSQ, porous methyl silsesquioxane (MSQ), porous polyarylether (PAE), and/or porous silicon oxide (SiOₓ), among other examples.

In some implementations, the dielectric layer 216 and the ESLs 214a-214c include different dielectric materials to provide etch selectivity. For example, the dielectric layer 216 may include a low-k dielectric material such as USG, and the ESLs 214a-214c may each include a high-k dielectric material such as silicon nitride (SiₓN_{y}) or silicon carbide (SiC), such that a dielectric constant of the ESLs 214a-214c is greater than a dielectric constant of the dielectric layer 216.

The photodetector structure 102 may include a plurality of contact structures 218a-218f (e.g., vias) disposed in portions of the dielectric layer 216. The contact structures 218a and 218b are further disposed through the second and third ESLs 214b and 214c, and land on the top surfaces of the p-doped region 204. The contact structures 218c and 218d are further disposed in the semiconductor layer 202, and land on different portions of a top surface of the n-doped region 206. The different portions of the top surface of the n-doped region 206 are on opposite lateral sides of the n-doped region 206 in the x-direction. The contact structures 218e and 218f are further disposed through portions of the second buffer layer 212b, and through portions of the first ESL 214a to land on the first buffer layer 212a.

The contact structures (contacts) 218a-218f may each include one or more conductive structures, where the conductive structures include a fill layer 220 and a liner layer 222. The fill layers 220 may include tungsten (W), cobalt (Co), ruthenium (Ru), titanium (Ti), aluminum (Al), copper (Cu), gold (Au), and/or a combination thereof, among other examples of electrically conductive materials. The liner layers 222, which are included on side and bottom surfaces of the contact structures 218a-218f, may include barrier liners, adhesion liners, and/or another type of liners. Examples of materials for the liner layers 222 include tantalum nitride (TaN) and/or titanium nitride (TiN), among other examples.

In some implementations, a vertical dimension D1 in the z-direction of the contact structures 218a and 218b is smaller than a vertical dimension D2 in the z-direction of the contact structures 218c and 218d. The vertical dimension D1 in the z-direction of the contact structures 218a and 218b is larger than a vertical dimension D3 in the z-direction of the contact structures 218e and 218f. The vertical dimension D2 in the z-direction of the contact structures 218c and 218d is greater than the vertical dimensions D1 and D3. As explained in more detail herein, the recesses for the contact structures 218a-218f are formed in a same etch operation by using the same mask structure, where the same etch operation includes applying an etchant to the photodetector structure 102 to etch different portions of the dielectric layer 216 and underlying layers to form contact structure recesses based on a pattern in the mask structure. The ESLs 214a-214c slow down etching of the recesses for the contact structures 218a, 218b, 218e, and 218f. As a result, the etching of recesses for the contact structures 218a-218f with different vertical dimensions D1-D3 may be performed in the same etch operation, where the etching of the recesses with the different vertical dimensions D1-D3 is completed at the same or approximately the same time.

In some implementations, the contact structures 218a and 218b may form ground connections, the contact structures 218c and 218d may form n-terminal connections, and the contact structures 218e and 218f may form p-terminal connections for a SPAD device.

In some implementations, an interconnect layer, including a first inter-layer dielectric (ILD) layer 224a, a second ILD layer 224b, and an interconnect layer ESL 226, is formed on the dielectric layer 216. The interconnect layer may further include metallization structures 228a-228f and 230a-230f, and interconnect structures 232a-232f, that are arranged to carry signals and/or provide power distribution for the photodetector structure 102. The first and second ILD layers 224a and 224b may include one or more of the dielectric materials referenced for the dielectric layer 216. The interconnect layer ESL 226 may include one or more of the dielectric materials referenced for the ESLs 214a-214c.

A first layer of metallization structures 228a-228f (referred to as a metal-1 (M1) layer) may be located at the bottom of the interconnect layer and may be coupled with the contact structures 218a-218f. In particular, the metallization structures 228a, 228b, 228c, 228d, 228e, and 228f in the M1 layer may be respectively coupled with the contact structures 218a, 218b, 218c, 218d, 218e, and 218f. A second layer of metallization structures 230a-230f (referred to as a metal-2 layer (M2) layer) may be located above the first layer of metallization structures 228a-228f in the interconnect layer, where the metallization structures 230a, 230b, 230c, 230d, 230e, and 230f are respectively coupled to the metallization structures 228a, 228b, 228c, 228d, 228e, and 228f by the interconnect structures 232a, 232b, 232c, 232d, 232e, and 232f.

The layer of interconnect structures 232a-232f (referred to as a via-1 (V1) layer) may be included between the M1 layer and the M2 layer to interconnect the M1 layer and the M2 layer.

The metallization structures 228a-228f and 230a-230f may include a combination of trenches, metallization layers, conductive traces, and/or other types of conductive structures. The interconnect structures 232a-232f may include a combination of vias, interconnects, and/or other types of conductive structures. The metallization structures 228a-228f and 230a-230f and the interconnect structures 232a-232f may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included between the dielectric layers of the interconnect layer and the metallization structures 228a-228f and 230a-230f, and/or between the dielectric layers of the interconnect layer and the interconnect structures 232a-232f. The one or more liner layers may include barrier liners, adhesion liners, and/or another type of liners. Examples of materials for the one or more liners include tantalum nitride (TaN) and/or titanium nitride (TiN), among other examples.

In some implementations, the topmost layer of conductive structures (e.g., the topmost layer of metallization structures 230a-230f) may be coupled to connection structures at the top of the semiconductor device 100. The connection structures may include solder balls, solder bumps, contact pads (e.g., land grid array (LGA) pads), contact pins (e.g., pin grid array (PGA) pins), under bump metallization (UBM) connections, microbumps, ball grid array (BGA) balls, controlled collapse chip connection (C4) bumps, and/or other types of connection structures. In some implementations, the topmost layer of conductive structures (e.g., the topmost layer of metallization structures 230a-230f) may be coupled to bonding structures, such as bonding pads and/or bonding vias.

As indicated above, FIG. 2 is provided as an example. Other examples may differ from what is described with regard to FIG. 2.

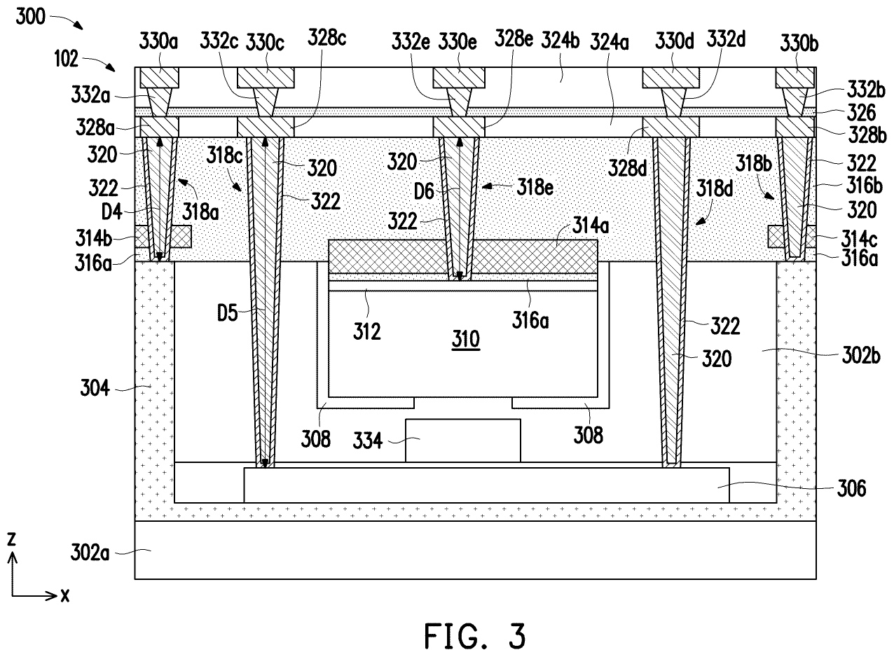

FIG. 3 is a diagram of an example implementation 300 of a photodetector structure 102 that may be included in a semiconductor device 100 described herein. The photodetector structure 102 may be a SPAD structure. As shown in FIG. 3, the photodetector structure 102 includes, or may be included in, a first semiconductor layer 302a (e.g., a substrate), and a second semiconductor layer 302b. The first semiconductor layer 302a may correspond to a substrate layer of the semiconductor device 100. Alternatively, the first semiconductor layer 302a may correspond to a top semiconductor layer of a silicon-on-insulator (SOI) substrate on which the semiconductor device 100 was formed. The first and second semiconductor layers 302a and 302b may include a semiconductor material such as silicon (Si), undoped silicon, silicon doped with p-type dopants (e.g., boron (B) and/or gallium (Ga), among other examples), silicon doped with n-type dopants (e.g., arsenic (As) and/or phosphorous (P), among other examples), and/or another semiconductor material. The first and second semiconductor layers 302a and 302b may include the same materials as each other or different materials from each other.

The first and second semiconductor layers 302a and 302b may include various doping configurations to satisfy one or more design parameters. For example, different doping profiles (e.g., n-wells, p-wells) may be formed in the first and second semiconductor layers 302a and 302b. The doping may be performed by ion implantation of dopants and/or diffusion processes. The photodetector structure 102 may include a plurality of doped regions that are included in the first and second semiconductor layers 302a and 302b. For example, the photodetector structure 102 may include a p-doped region 304 in portions of the first and second semiconductor layers 302a and 302b, an n-doped region 306 in the first semiconductor layer 302a, p-doped regions 308 in the second semiconductor layer 302b, and a p-doped region 334 in the second semiconductor layer 302b. The p-doped region 304, the p-doped regions 308, and the p-doped region 334 may be regions of the first and/or second semiconductor layers 302a and 302b that are doped with one or more p-type dopants, such as boron (B), gallium (Ga), and/or indium (In), among other examples. The n-doped region 306 may be a region of the first semiconductor layer 302a that is doped with one or more n-type dopants, such as phosphorous (P), arsenic (As), bismuth (Bi), and/or antimony (Sb), among other examples. The p-doped region 304 is formed in a U-shape around the n-doped region 306. The p-doped region 304 is formed on lateral sides of and under the n-doped region 306. In some implementations, the p-doped region 304 is in physical contact with a bottom surface of the n-doped region 306.

The photodetector structure 102 includes a photon absorption region 310 (e.g., absorption layer) in the second semiconductor layer 302b. The photon absorption region 310 is in physical contact with L-shaped p-doped regions 308, which are disposed on sides of the photon absorption region 310 and under portions of a bottom surface of the photon absorption region 310.

The photon absorption region 310 may be configured to absorb photons of incident light and convert the photons to electrons through the photoelectric effect. A SPAD may be biased at fields greater than an avalanche breakdown so that avalanche breakdown may be used to detect individual photons. In other words, an avalanche current may be triggered by a single photon incident on the photon absorption region 310. In some implementations, the p-doped regions 308 function as charge sheets to control an electric field so that the electric field is high enough in a region (e.g., collection region) between the photon absorption region 310 and the n-doped region 306 to permit avalanche breakdown to be reached, and low enough in the photon absorption region 310 to prevent tunneling. The p-doped region 334 is in the second semiconductor layer 302b, and is disposed in the collection region between the photon absorption region 310 and the n-doped region 306.

The photons interact with electron-hole pairs in the photon absorption region 310. The interaction causes electrons and holes to be separated and to migrate toward the collection region between the photon absorption region 310 and the n-doped region 306 in the semiconductor layer 202, resulting in the generation of an electric field (e.g., a built-in electric field). The accumulation of holes and the accumulation of electrons at the collection region cause a photocurrent to be generated. The magnitude of the photocurrent may be proportional to the amount of photons that is collected in the photon absorption region 310. Accordingly, the photocurrent that is generated may be an indication of the intensity of the incident light.

The photon absorption region 310 may include a semiconductor material. The semiconductor material of the photon absorption region 310 may be the same as the semiconductor material of the first and/or second semiconductor layers 302a, 302b. Additionally and/or alternatively, the semiconductor material of the photon absorption region 310 and the semiconductor material of the first and/or second semiconductor layers 302a, 302b may be different semiconductor materials. Examples of semiconductor materials for the photon absorption region 310 include germanium (Ge), germanium tin (GeSn), silicon germanium (SiGe), indium gallium arsenide (InGaAs), and/or gallium arsenide (GaAs), among other examples.

In some implementations, a buffer layer 312 is disposed on a top surface of the photon absorption region 310, a first dielectric layer 316a is disposed on the buffer layer 312, and a first ESL 314a is disposed on the first dielectric layer 316a. With the exception of a top portion of the first ESL 314a, a stacked arrangement in the z-direction of the photon absorption region 310, the buffer layer 312 on the photon absorption region 310, the first dielectric layer 316a on the buffer layer 312, and a bottom portion of the first ESL 314a on the first dielectric layer 316a, is disposed in the second semiconductor layer 302b. A second ESL 314b and a third ESL 314c are disposed on portions of the first dielectric layer 316a over top surfaces of the p-doped region 304 on opposite lateral sides of the photodetector structure 102 in the x-direction. In some implementations, the buffer layer 312 includes a semiconductor material such as silicon (Si), and the ESLs 314a-314c may include a silicon nitride (SiₓN_{y}), silicon carbide (SiC), silicon oxynitride (SiON), and/or another suitable dielectric material. The ESLs 314a-c may be in physical contact with portions of the first dielectric layer 316a. In some implementations, the first ESL 314a is partially recessed in the second semiconductor layer 302b. Alternatively, a bottom surface of the ESL 214a is coplanar or approximately coplanar with a top surface of the second semiconductor layer 302b.

A second dielectric layer 316b is disposed on the first dielectric layer 316a. The second dielectric layer 316b is further disposed on a top surface and around sides of the top portion of the first ESL 214a, and on a top surface and around sides of the second and third ESLs 314b and 314c. The first and second dielectric layers 316a and 316b may include a low dielectric constant (low-k) oxide material such as silicon oxide (SiOₓ) or undoped silicate glass (USG). Additionally and/or alternatively, the first and second dielectric layers 316a and 316b may include a boron-containing silicate glass (BSG), a fluorine-containing silicate glass (FSG), tetraethyl orthosilicate (TEOS), hydrogen silsesquioxane (HSQ), and/or another suitable dielectric material. In some implementations, the first and second dielectric layers 316a and 316b include an extreme low dielectric constant (ELK) dielectric material having a dielectric constant that is less than approximately 2.5. Examples of ELK dielectric materials include carbon doped silicon oxide (C—SiOₓ), amorphous fluorinated carbon (α-CₓF_{y}), parylene, bis-benzocyclobutenes (BCB), polytetrafluoroethylene (PTFE), a silicon oxycarbide (SiOC) polymer, porous HSQ, porous methyl silsesquioxane (MSQ), porous polyarylether (PAE), and/or porous silicon oxide (SiOₓ), among other examples.

In some implementations, the first and second dielectric layers 316a and 316b and the ESLs 314a-314c include different dielectric materials to provide etch selectivity. For example, the first and second dielectric layers 316a and 316b may include a low-k dielectric material such as USG, and the ESLs 314a-314c may each include a high-k dielectric material such as silicon nitride (SiₓN_{y}) or silicon carbide (SiC), such that a dielectric constant of the ESLs 314a-314c is greater than a dielectric constant of the first and second dielectric layers 316a and 316b.

The photodetector structure 102 may include a plurality of contact structures 318a-318e (e.g., vias) disposed in portions of the first and second dielectric layers 316a and 316b. The contact structures 318a and 318b are further disposed through the second and third ESLs 314b and 314c, and land on the top surfaces of the p-doped region 304. The contact structures 318c and 318d are further disposed in the first and second semiconductor layers 302a and 302b, and land on different portions of a top surface of the n-doped region 306. The different portions of the top surface of the n-doped region 306 are on opposite lateral sides of the n-doped region 306 in the x-direction. The contact structure 318e is further disposed through a portions of the first ESL 314a, and through a portion of the first dielectric layer 316a to land on the buffer layer 312.

The contact structures (contacts) 318a-318e may each include one or more conductive structures, where the conductive structures include a fill layer 320 and a liner layer 322. The fill layers 320 may include tungsten (W), cobalt (Co), ruthenium (Ru), titanium (Ti), aluminum (Al), copper (Cu), gold (Au), and/or a combination thereof, among other examples of electrically conductive materials. The liner layers 322, which are included on side and bottom surfaces of the contact structures 318a-318e, may include barrier liners, adhesion liners, and/or another type of liners. Examples of materials for the liner layers 322 include tantalum nitride (TaN) and/or titanium nitride (TiN), among other examples.

In some implementations, a vertical dimension D4 in the z-direction of the contact structures 318a and 318b is smaller than a vertical dimension D5 in the z-direction of the contact structures 318c and 318d. The vertical dimension D4 in the z-direction of the contact structures 318a and 318b is smaller than a vertical dimension D6 in the z-direction of the contact structure 318e. The vertical dimension D5 in the z-direction of the contact structures 318c and 318d is greater than the vertical dimensions D4 and D6. As explained in more detail herein, the recesses for the contact structures 318a-318e are formed in a same etch operation by using the same mask structure, where the same etch operation includes applying an etchant to the photodetector structure 102 to etch different portions of the second dielectric layer 316b and underlying layers to form contact structure recesses based on a pattern in the mask structure. The ESLs 314a-314c slow down etching of the recesses for the contact structures 318a, 318b, and 318e. As a result, the etching of recesses for the contact structures 318a-318e with different vertical dimensions D4-D6 may be performed in the same etch operation, where the etching of the recesses with the different vertical dimensions D4-D6 is completed at the same or approximately the same time.

In some implementations, the contact structures 318a and 318b may form ground connections, the contact structures 318c and 318d may form n-terminal connections, and the contact structure 318e may form a p-terminal connection for a SPAD device.

In some implementations, an interconnect layer including a first inter-layer dielectric (ILD) layer 324a, a second ILD layer 324b, and an interconnect layer ESL 326 is formed on the second dielectric layer 316b. The interconnect layer may further include metallization structures 328a-328e and 330a-330e, and interconnect structures 332a-332e, that are arranged to carry signals and/or provide power distribution for the photodetector structure 102. The first and second ILD layers 324a and 324b may include one or more of the dielectric materials referenced for the first and second dielectric layers 316a and 316b. The interconnect layer ESL 326 may include one or more of the dielectric materials referenced for the ESLs 314a-314c.

A first layer of metallization structures 328a-328e (referred to as a metal-1 (M1) layer) may be located at the bottom of the interconnect layer and may be coupled with the contact structures 318a-318e. In particular, the metallization structures 328a, 328b, 328c, 328d, and 328e in the M1 layer may be respectively coupled with the contact structures 318a, 318b, 318c, 318d, and 318e. A second layer of metallization structures 330a-330e (referred to as a metal-2 layer (M2) layer) may be located above the first layer of metallization structures 328a-328e in the interconnect layer, where the metallization structures 330a, 330b, 330c, 330d, and 330e are respectively coupled to the metallization structures 328a, 328b, 328c, 328d, and 328e by the interconnect structures 332a, 332b, 332c, 332d, and 332e.

The layer of interconnect structures 332a-332e (referred to as a via-1 (V1) layer) may be included between the M1 layer and the M2 layer to interconnect the M1 layer and the M2 layer.

The metallization structures 328-328e and 330a-330e may include a combination of trenches, metallization layers, conductive traces, and/or other types of conductive structures. The interconnect structures 332a-332e may include a combination of vias, interconnects, and/or other types of conductive structures. The metallization structures 328a-328e and 330a-330e and the interconnect structures 332a-332e may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included between the dielectric layers of the interconnect layer and the metallization structures 328a-328e and 330a-330e, and/or between the dielectric layers of the interconnect layer and the interconnect structures 332a-332e. The one or more liner layers may include barrier liners, adhesion liners, and/or another type of liners. Examples of materials for the one or more liners include tantalum nitride (TaN) and/or titanium nitride (TiN), among other examples.

In some implementations, the topmost layer of conductive structures (e.g., the topmost layer of metallization structures 330a-330e) may be coupled to connection structures at the top of the semiconductor device 100. The connection structures may include solder balls, solder bumps, contact pads (e.g., land grid array (LGA) pads), contact pins (e.g., pin grid array (PGA) pins), under bump metallization (UBM) connections, microbumps, ball grid array (BGA) balls, controlled collapse chip connection (C4) bumps, and/or other types of connection structures. In some implementations, the topmost layer of conductive structures (e.g., the topmost layer of metallization structures 330a-330e) may be coupled to bonding structures, such as bonding pads and/or bonding vias.

As indicated above, FIG. 3 is provided as an example. Other examples may differ from what is described with regard to FIG. 3.

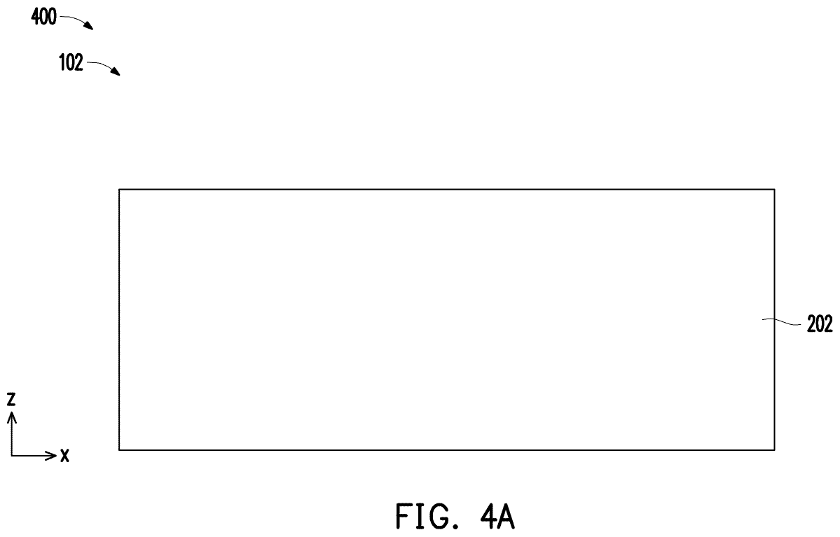

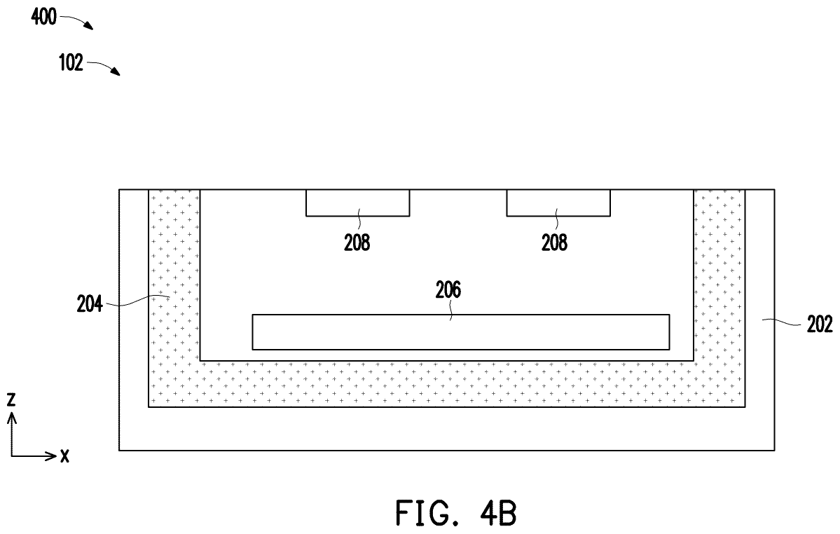

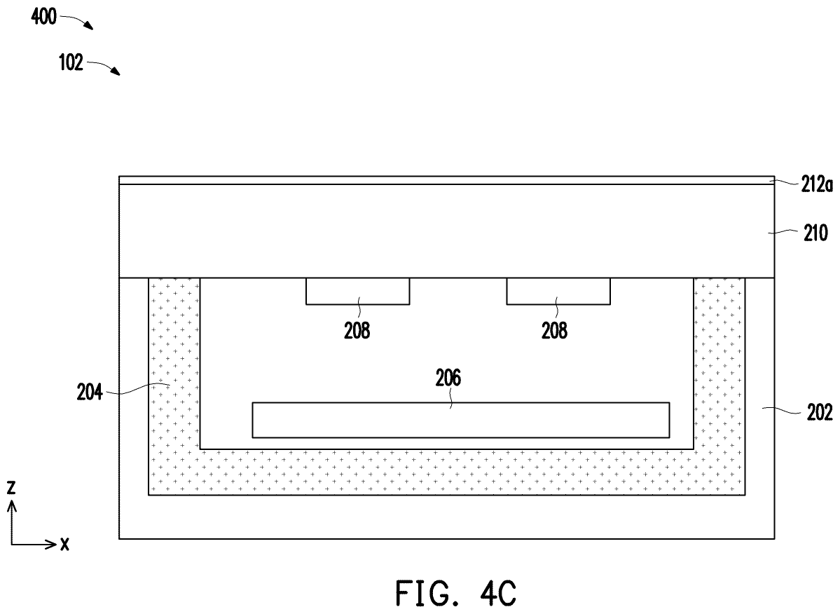

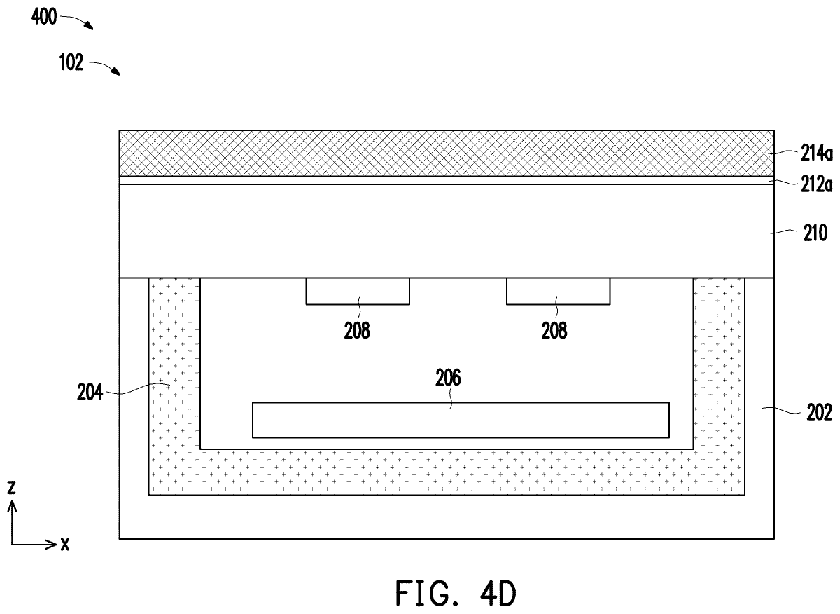

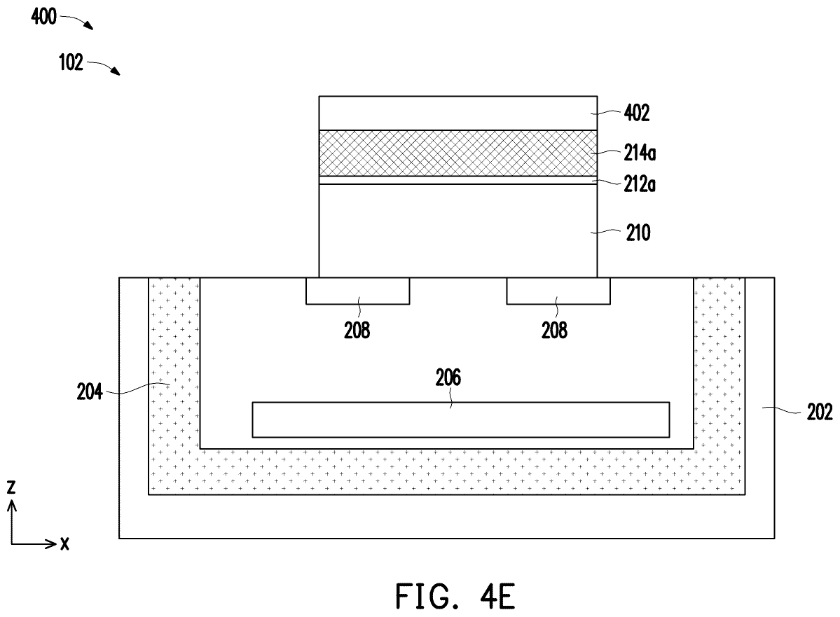

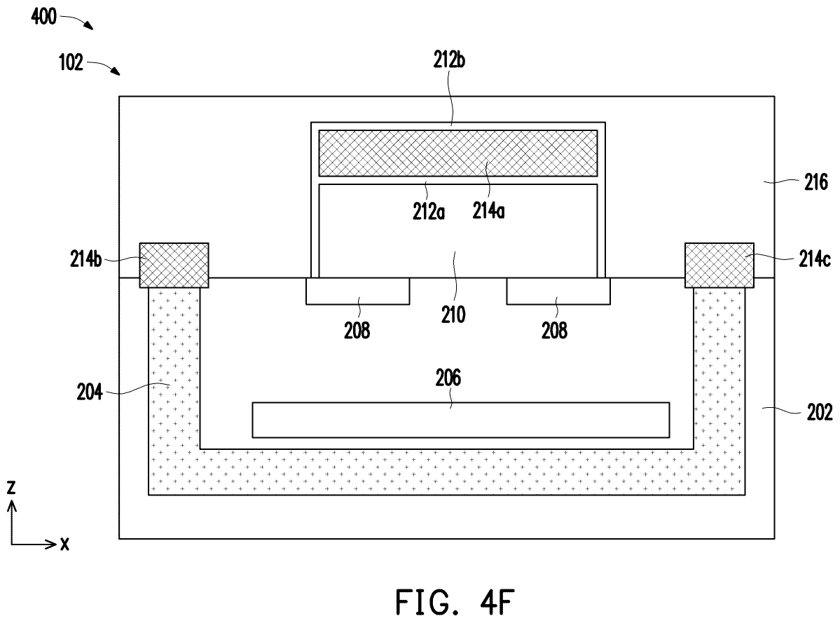

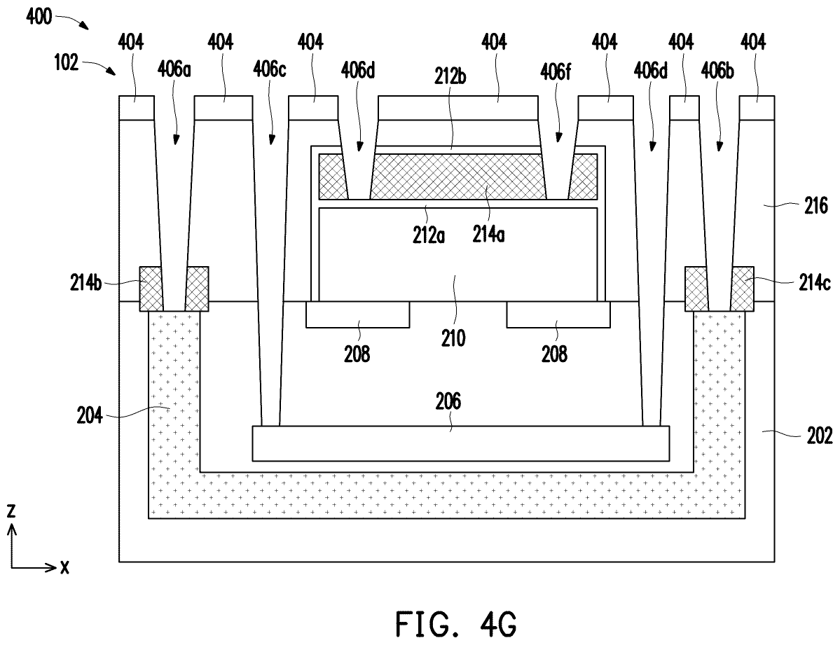

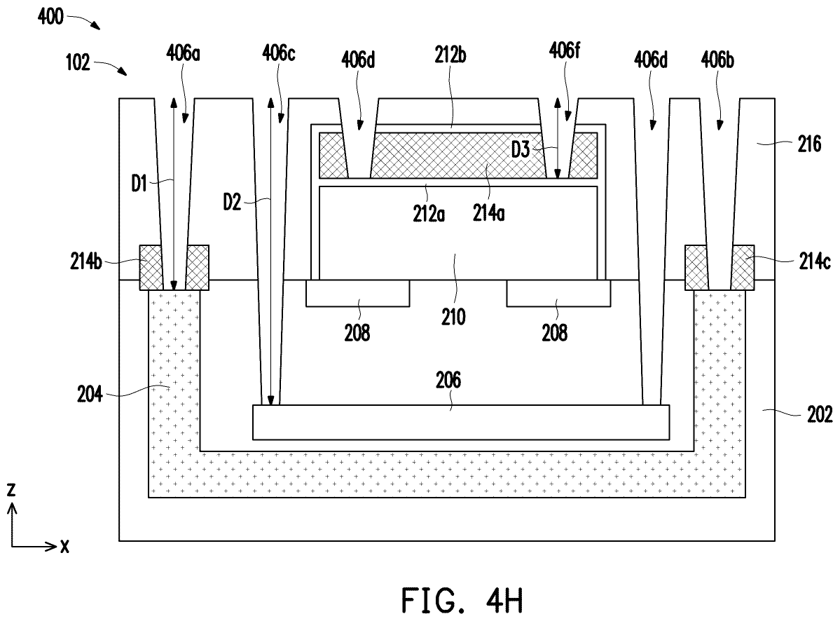

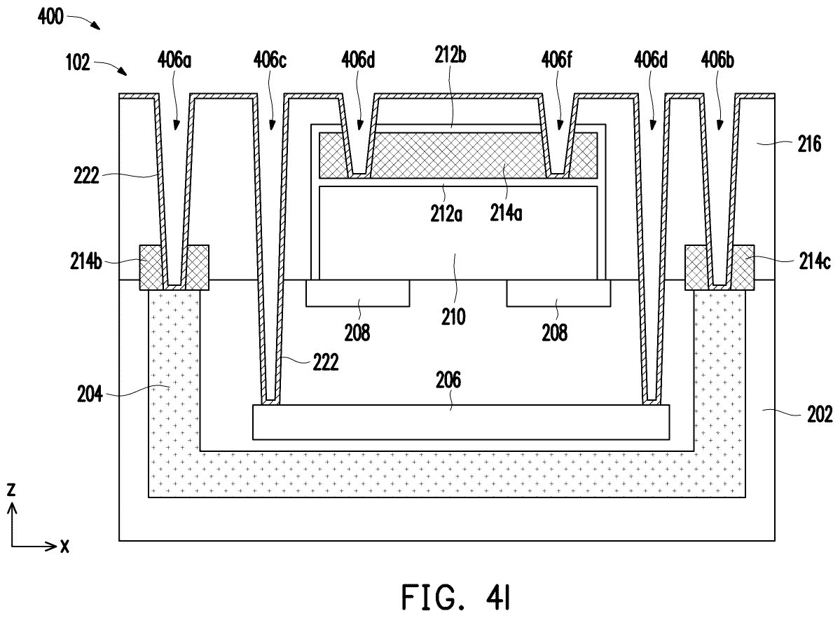

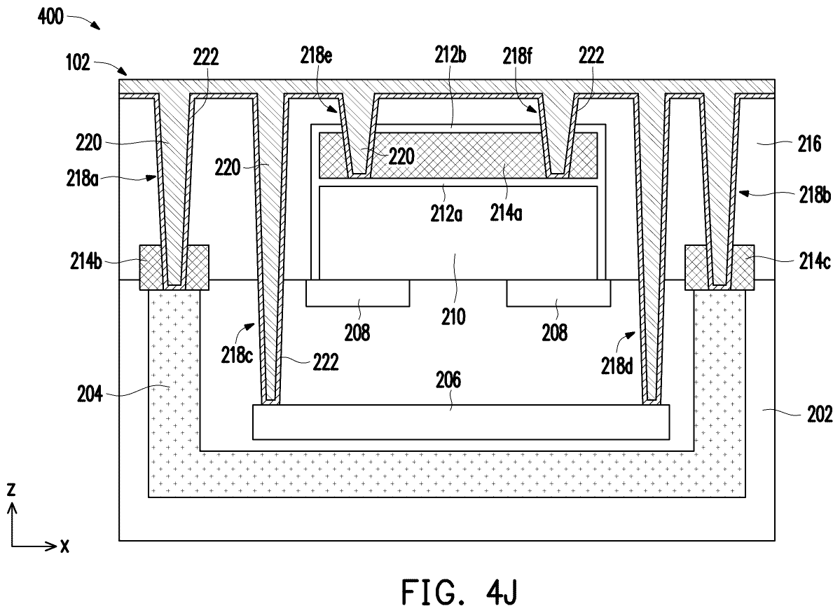

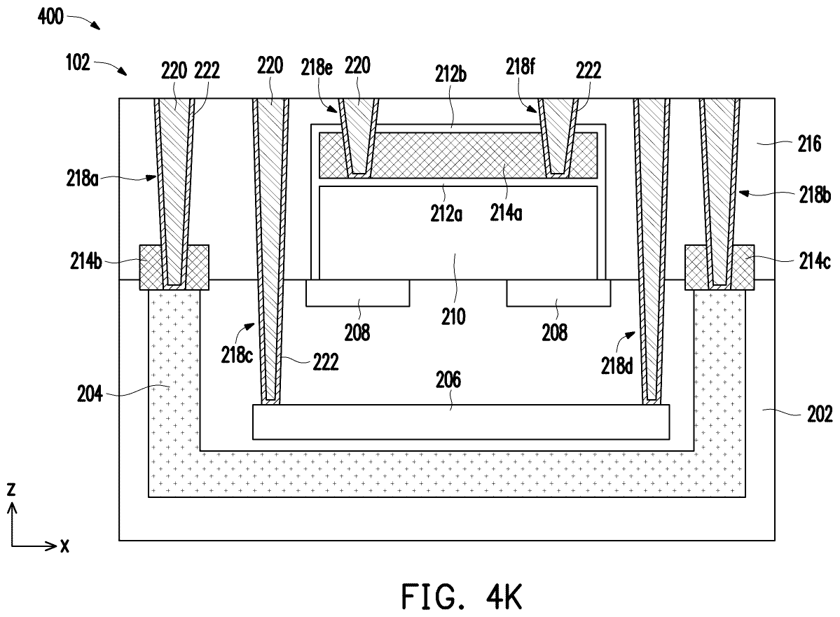

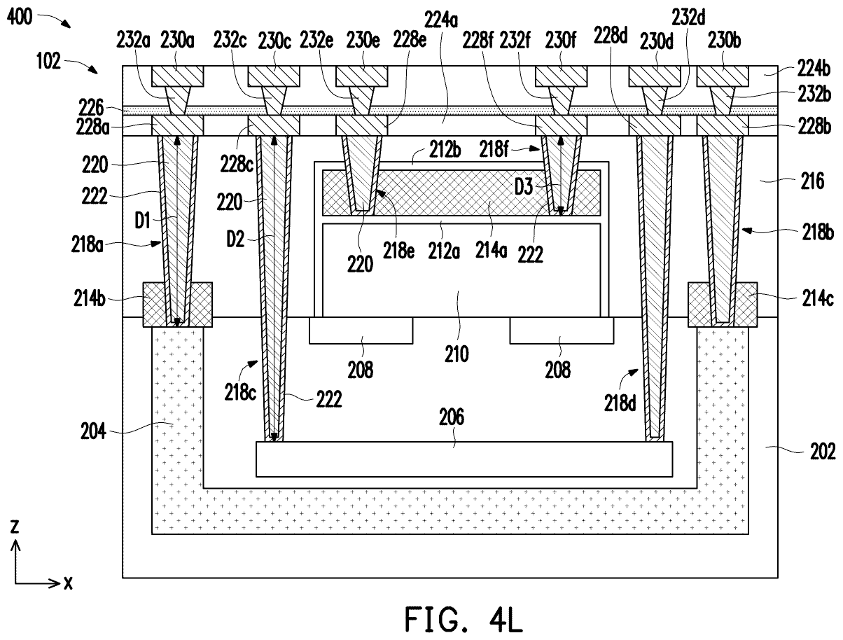

FIGS. 4A-4L are diagrams of an example implementation 400 of forming a photodetector structure 102 described herein. While the example implementation 400 includes an example of forming the example implementation 200 of the photodetector structure 102 illustrated and described in connection with FIG. 2, the semiconductor processing operations and/or techniques illustrated and described in connection with FIGS. 4A-4L (or a subset thereof) may be used to manufacture other example implementations of photodetector structures 102 illustrated and described herein. In some implementations, one or more of the semiconductor processing operations described in connection with FIGS. 4A-4L are performed by one or more semiconductor processing tools and/or a wafer/die transport tool.

Turning to FIG. 4A, a semiconductor layer 202 in the form of a substrate may be provided. The semiconductor layer 202 may be provided as a semiconductor wafer, a semiconductor die, and/or another type of semiconductor substrate. In some implementations, the semiconductor layer 202 may be a doped substrate, such as a semiconductor substrate that is doped with one or more p-type dopants, a semiconductor substrate that is doped with one or more n-type dopants, and/or another type of doped substrate.

As shown in FIG. 4B, one or more implantation operations may be performed to form the p-doped region 204, the n-doped region 206, and the p-doped regions 208 in the semiconductor layer 202. The n-doped region 206 may be formed below the surface of the semiconductor layer 202. The p-doped region 204 and the p-doped regions 208 may be formed at the surface of the semiconductor layer 202 and extend below the surface of the semiconductor layer 202. Moreover, the p-doped regions 208 may be formed such that the p-doped regions 208 are spaced apart from one another by a portion of the semiconductor layer 202. The n-doped region 206 may be spaced apart from the p-doped region 204, and from the p-doped regions 208.

In some implementations, an ion implantation tool performs the one or more implantation operations to form the p-doped region 204 and the p-doped regions 208 in the semiconductor layer 202 by performing an ion implantation operation to implant ions (e.g., p-type ions) into the semiconductor layer 202 to form the p-doped region 204 and the p-doped regions 208. In some implementations, an ion implantation tool performs the one or more implantation operations to form the n-doped region 206 in the semiconductor layer 202 by performing an ion implantation operation to implant ions (e.g., n-type ions) into the semiconductor layer 202 to form the n-doped region 206. The ion implantation tool may direct an ion beam toward the semiconductor layer 202 such that the ions are implanted below the surface of the semiconductor layer 202 to dope the semiconductor layer 202. One or more implantation masks may be formed on the semiconductor layer 202, and patterns formed in the one or more implantation masks may be used to form the p-doped region 204, the n-doped region 206, and the p-doped regions 208 in the semiconductor layer 202 in the arrangement shown in FIG. 4B.

As shown in FIG. 4C, one or more types of deposition tools may be used to deposit and/or grow the photon absorption region 210 on the semiconductor layer 202, and to grow the first buffer layer 212a on the photon absorption region 210. For example, a deposition tool may be used to grow the photon absorption region 210 and/or the first buffer layer 212a by epitaxial growth, which may include epitaxy techniques such as a molecular beam epitaxy (MBE), metalorganic chemical vapor deposition (MOCVD) process, and/or another suitable epitaxy technique. Additionally and/or alternatively, the photon absorption region 210 and/or the first buffer layer 212a may be deposited by chemical vapor deposition (CVD), physical vapor deposition (PVD), atomic layer deposition (ALD), and/or another suitable deposition technique.

As shown in FIG. 4D, the first ESL 214a is deposited on the first buffer layer 212a. In some implementations, the first ESL 214a may be deposited by a CVD, PVD, ALD, and/or another suitable deposition technique.

As shown in FIG. 4E, the first ESL 214a, the first buffer layer 212a, and the photon absorption region 210 may be etched to pattern the first ESL 214a, the first buffer layer 212a, and the photon absorption region 210. In some implementations, a pattern in a photoresist layer 402 is used to define regions of the first ESL 214a, the first buffer layer 212a, and the photon absorption region 210 to etch. In these implementations, a deposition tool may be used to form the photoresist layer 402 on the first ESL 214a. An exposure tool may be used to expose the photoresist layer 402 to a radiation source to pattern the photoresist layer 402. A developer tool may be used to develop and remove portions of the photoresist layer 402 to expose the pattern. An etch tool may be used to etch the first ESL 214a, the first buffer layer 212a, and the photon absorption region 210 based on the pattern. In some implementations, the etch operation includes a plasma etch operation, a wet chemical etch operation, and/or another type of etch operation. In some implementations, a photoresist removal tool may be used to remove the remaining portions of the photoresist layer 402 (e.g., using a chemical stripper, plasma ashing, and/or another technique). In some implementations, a hard mask layer is used as an alternative technique for etching the first ESL 214a, the first buffer layer 212a, and the photon absorption region 210 based on a pattern.

As shown in FIG. 4F, following removal of the remaining portions of the photoresist layer 402, a second buffer layer 212b is deposited on a top surface of the first ESL 214a, and on side surfaces of the first ESL 214a, the first buffer layer 212a, and the photon absorption region 210. The second buffer layer 212b may be deposited by CVD, ALD, and/or another suitable deposition technique on and around the first ESL 214a, the first buffer layer 212a, and the photon absorption region 210, and on exposed portions of the semiconductor layer 202. Portions of the second buffer layer 212b may be removed from the semiconductor layer 202 in an etch process.

Following deposition and patterning of the second buffer layer 212b, second and third ESLs 214b and 214c are formed on the top surfaces of the p-doped region 204 on opposite lateral sides of the photodetector structure 102 in the x-direction. In some implementations, the second and third ESLs 214b and 214c are partially recessed in the semiconductor layer 202. Alternatively, bottom surfaces of the second and third ESLs 214b and 214c may be on a top surface of the semiconductor layer 202. In some implementations, a blanket ESL is deposited on the semiconductor layer 202 and on the second buffer layer 212b, and then patterned in an etch operation to form the second and third ESLs 214b and 214c.

Following the formation of the second and third ESLs 214b and 214c, the dielectric layer 216 is deposited on and around the stacked arrangement of the photon absorption region 210, the first buffer layer 212a, the first ESL 214a, and the second buffer layer 212b, on and around the second and third ESLs 214b and 214c, and on the semiconductor layer 202. The dielectric layer 216 may be deposited by a CVD, PVD, ALD, and/or another suitable deposition technique, which may be followed by a planarization process (e.g., a chemical mechanical planarization (CMP) process).

As shown in FIG. 4G, a dielectric masking layer 404 may be formed on the dielectric layer 216. The dielectric masking layer 404 may include a silicon oxynitride material (SiON) and/or another suitable dielectric material. A deposition tool may be used to deposit the dielectric masking layer 404 using a PVD technique, an ALD technique, a CVD technique, an oxidation technique, and/or another suitable deposition technique. In some implementations, a planarization tool is used to perform a planarization operation (e.g., a CMP operation) to planarize the dielectric masking layer 404 after the dielectric masking layer 404 is deposited.

A photoresist layer may be formed above the dielectric masking layer 404, and a pattern may be formed in the photoresist layer. A deposition tool may be used to form the photoresist layer on the dielectric masking layer 404 (e.g., using a spin-coating technique or another suitable deposition technique). In some implementations, a BARC is first deposited on the dielectric masking layer 404, and then the photoresist layer is deposited onto the BARC. An exposure tool may be used to expose the photoresist layer to a radiation source to pattern the photoresist layer. A developer tool may be used to develop and remove portions of the photoresist layer to expose the pattern.

An etch tool may be used to etch the dielectric masking layer 404 based on the pattern in the photoresist layer, to transfer the pattern to the dielectric masking layer 404. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique).

Another etch operation may be performed to etch through portions of the dielectric layer 216, portions of the second buffer layer 212b, portions of the ESLs 214a-214c, and/or portions of the semiconductor layer 202 to form recesses 406a, 406b, 406c, 406d, 406e, and 406f. The recesses 406a and 406b are respectively formed through the dielectric layer 216 and through the second and third ESLs 214b and 214c. Bottom surfaces of the recesses 406a and 406b expose portions of the top surfaces of the p-doped region 204. The recesses 406c and 406d are respectively formed through the dielectric layer 216, and in the semiconductor layer 202. Bottom surfaces of the recesses 406c and 406d expose portions of the top surfaces of the n-doped region 206. The recesses 406e and 406f are respectively formed through the dielectric layer 216, through the second buffer layer 212b, and through portions of the first ESL 214a. Bottom surfaces of the recesses 406e and 406f expose portions of the top surface of the first buffer layer 212a. The etch operation may include, for example, a gas-based etch operation in which a different type of etchant is used, as compared to the etchant that was used to transfer the pattern to the dielectric masking layer 404. Thus, the semiconductor device 100 may be transferred from a first etch tool (in which the pattern was transferred to the dielectric masking layer 404) to a second etch tool (in which the dielectric layer 216, the second buffer layer 212b, the ESLs 214a-214c, and/or the semiconductor layer 202 are etched) using a wafer/die transport tool to reduce the likelihood of cross-contamination between the first and second etch tools. Alternatively, an etch tool that has multiple processing chambers (e.g., a cluster tool) may be used, and the semiconductor device 100 may be transferred between processing chambers of the etch tool for etching using different types of etchants.

As shown in FIG. 4H, the dielectric masking layer 404 may be removed. In some implementations, a vertical dimension D1 in the z-direction of the recesses 406a and 406b may be the same as that of the contact structures 218a and 218b, and is smaller than a vertical dimension D2 in the z-direction of the recesses 406c and 406d. The vertical dimension D2 in the z-direction of the recesses 406c and 406d may be the same as that of contact structures 218c and 218d. The vertical dimension D1 in the z-direction of the recesses 406a and 406b is larger than a vertical dimension D3 in the z-direction of the recesses 406e and 406f. The vertical dimension D3 in the z-direction of the recesses 406e and 406f may be the same as that of the contact structures 218e and 218f. The vertical dimension D2 in the z-direction of the recesses 406c and 406f is greater than the vertical dimensions D1 and D3.

The recesses 406a-406f are formed in a same etch operation by using the same mask structure (e.g., dielectric masking layer 404), where the same etch operation includes applying an etchant (e.g., a gas-based etchant) to the photodetector structure 102 to etch different portions of the dielectric layer 216 and underlying layers to form the recesses 406a-406f based on a pattern in the dielectric masking layer 404. The ESLs 214a-214c slow down etching of the recesses 406a, 406b, 406e, and 406f with smaller vertical dimensions D1 and D3 than the vertical dimension D2 of the recesses 406c and 406d. The etch rates of the ESLs 214a-214c are slower than the etch rate of the dielectric layer 216, and slower than the etch rate of the semiconductor layer 202. As a result, the etching of recesses 406a-406f for the contact structures 218a-218f with different vertical dimensions D1-D3 may be performed in the same etch operation, where the etching of the recesses 406a-406f with the different vertical dimensions D1-D3 is completed at the same or approximately the same time. The vertical dimension in the z-direction (e.g., thickness) of the ESLs 214a-214c may be controlled to ensure that etching of the recesses 406a-406f with the different vertical dimensions D1-D3 is completed at the same or approximately the same time.

As shown in FIG. 4I, the liner layer 222 may be deposited on the sidewalls and on the bottom surfaces of the recesses 406a-406f. The bottom surfaces of the recesses 406a and 406b correspond to the top surfaces of the p-doped region 204, the bottom surfaces of the recesses 406c and 406d correspond to the top surface of the n-doped region 206, and the bottom surfaces of the recesses 406e and 406f correspond to the top surface of the first buffer layer 212a. Thus, the liner layer 222 may be in physical contact with the top surfaces of the p-doped region 204, n-doped region 206, and first buffer layer 212a. The liner layer 222 may also be deposited on the top surface of the dielectric layer 216 between adjacent recesses 406. In some implementations, a deposition tool is used to conformally deposit the liner layer 222 such that the liner layer 222 conforms to the profile of the recesses 406a-406f. In some implementations, a conformal CVD technique and/or an ALD technique is used to deposit the liner layer 222.

As shown in FIG. 4J, the fill layer 220 may be deposited on the liner layer 222. The fill layer 220 may be deposited such that the fill layer 220 fills the remaining areas of the recesses 406a-406f. The fill layer 220 may also be deposited on the top surface of the liner layer 222 between recesses 406. As shown in FIG. 4K, the fill layer 220 and the liner layer 222 are removed from the top surface of the dielectric layer 216 in a subsequent CMP operation. In some implementations, a deposition tool is used to deposit the fill layer 220 using a PVD technique, a CVD technique, an ALD technique, and/or another suitable deposition technique to form the contact structures 218a-218f including the fill layers 220 and the liner layers 222.

As shown in FIG. 4L, the interconnect layer including the ILD layers 224a and 224b, and the interconnect layer ESL 226, is formed over the dielectric layer 216 and the contact structures 218a-218f. One or more deposition tools are used to deposit alternating layers of ILD layers 224a and 224b, and the interconnect layer ESL 226. In this way, the ILD layers 224a and 224b and the interconnect layer ESL 226 may be arranged in the z-direction in the semiconductor device 100. One or more deposition tools may be used to deposit each of the ILD layers 224a and 224b and the interconnect layer ESL 226 using a PVD technique, an ALD technique, a CVD technique, an oxidation technique, and/or another suitable deposition technique. In some implementations, a planarization tool may be used to planarize the ILD layers 224a and 224b and/or the interconnect layer ESL 226 after the ILD layers 224a and 224b and/or the interconnect layer ESL 226 are deposited.

As further shown in FIG. 4L, a deposition tool, an exposure tool, a developer tool, an etch tool, a planarization tool, a plating tool, and/or another semiconductor processing tool may be used to perform various operations to form the metallization structures 228a-228f and 230a-230f, and to form the interconnect structures 232a-232f.

One or more deposition tools may be used to deposit the metallization structures 228a-228f and 230a-230f and/or the interconnect structures 232a-232f using a PVD technique, an ALD technique, a CVD technique, an electroplating technique (e.g., an electro-chemical plating technique), and/or another suitable deposition technique. In some implementations, a planarization tool may be used to planarize the metallization structures 228a-228f and 230a-230f and/or the interconnect structures 232a-232f after the metallization structures 228a-228f and 230a-230f and/or the interconnect structures 232a-232f are deposited.

As indicated above, FIGS. 4A-4L are provided as an example. Other examples may differ from what is described with regard to FIGS. 4A-4L.

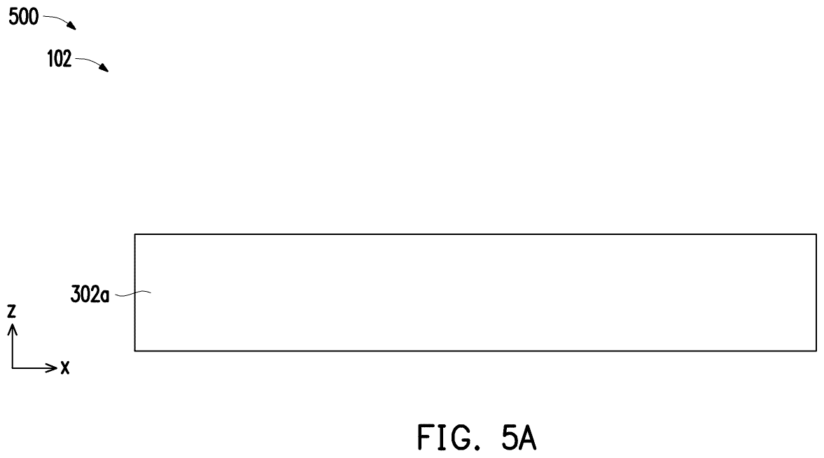

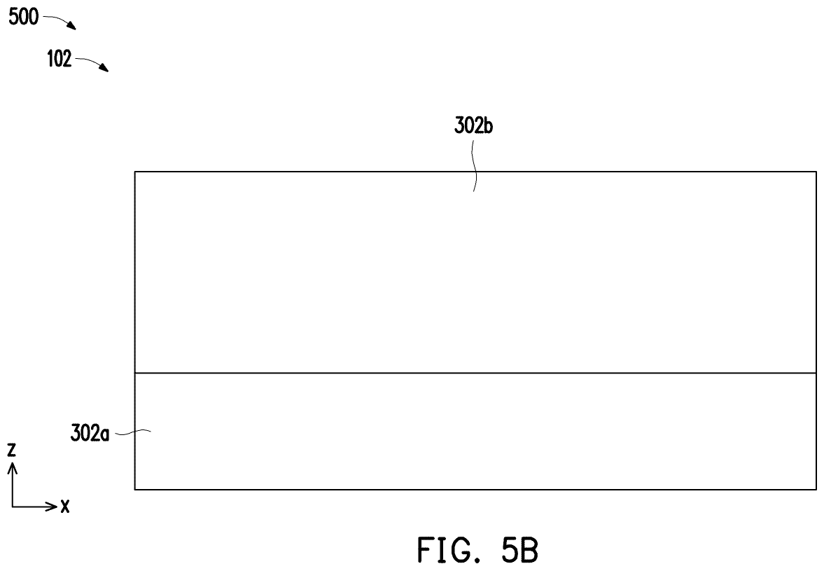

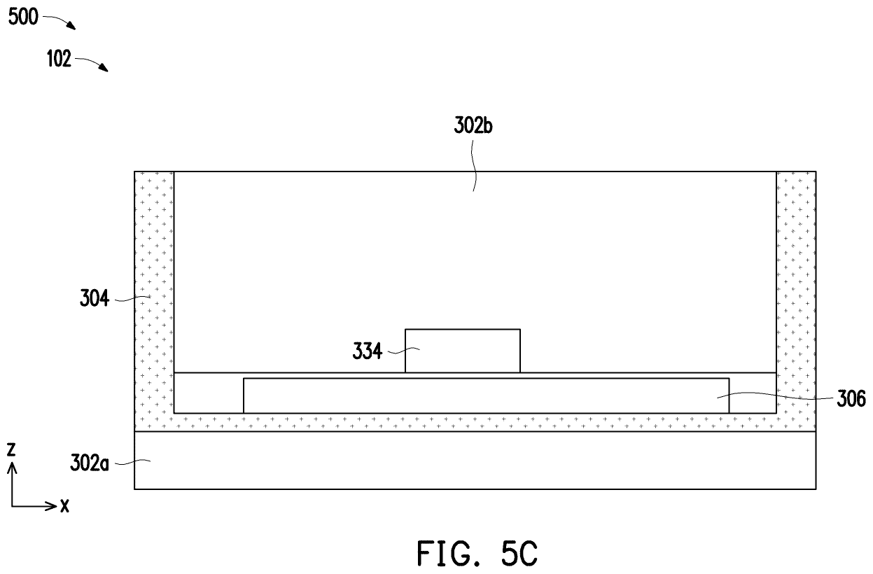

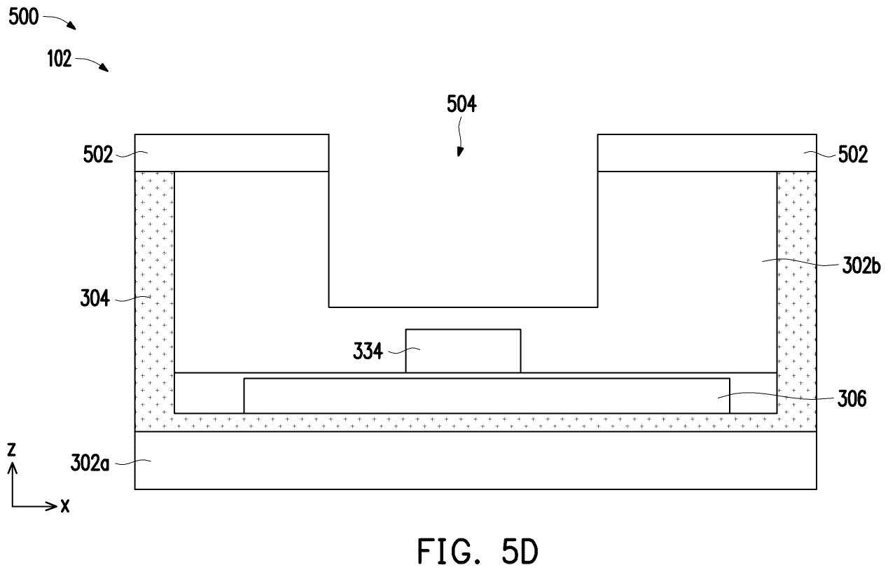

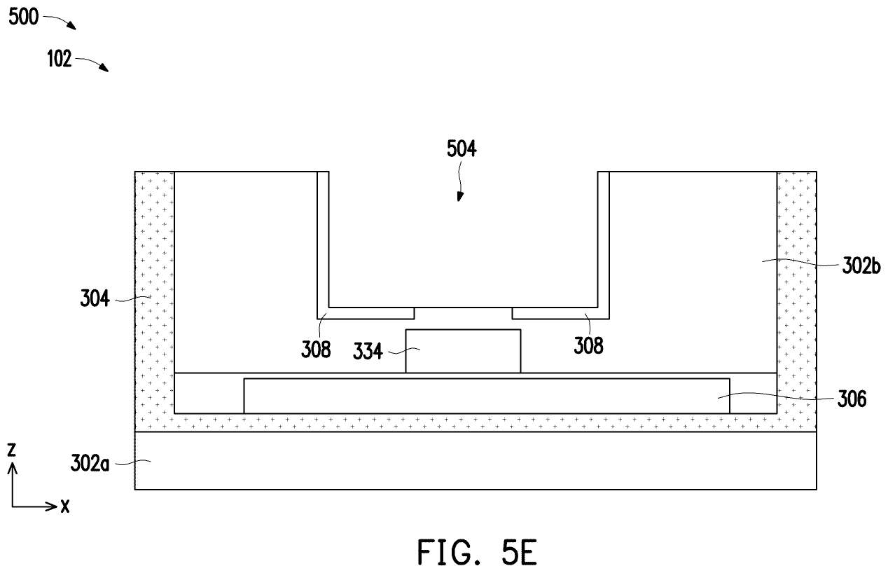

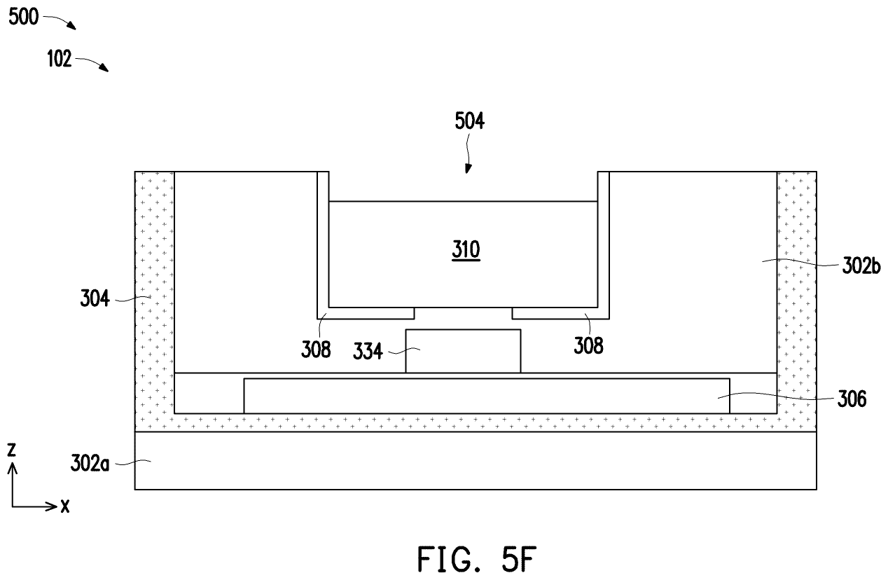

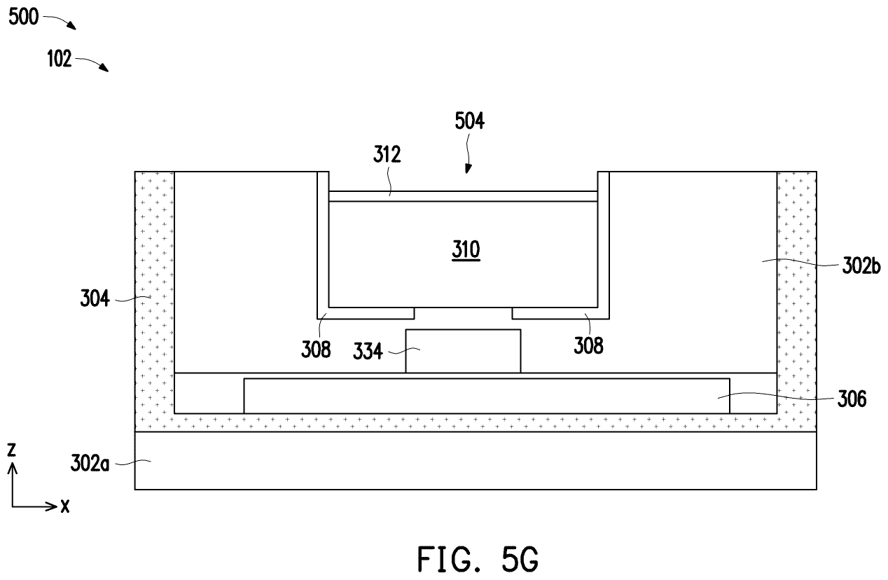

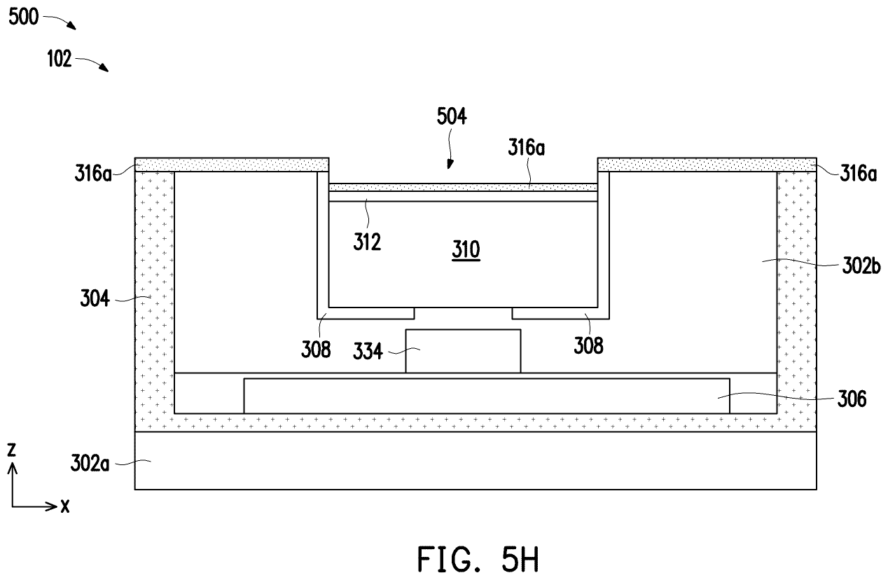

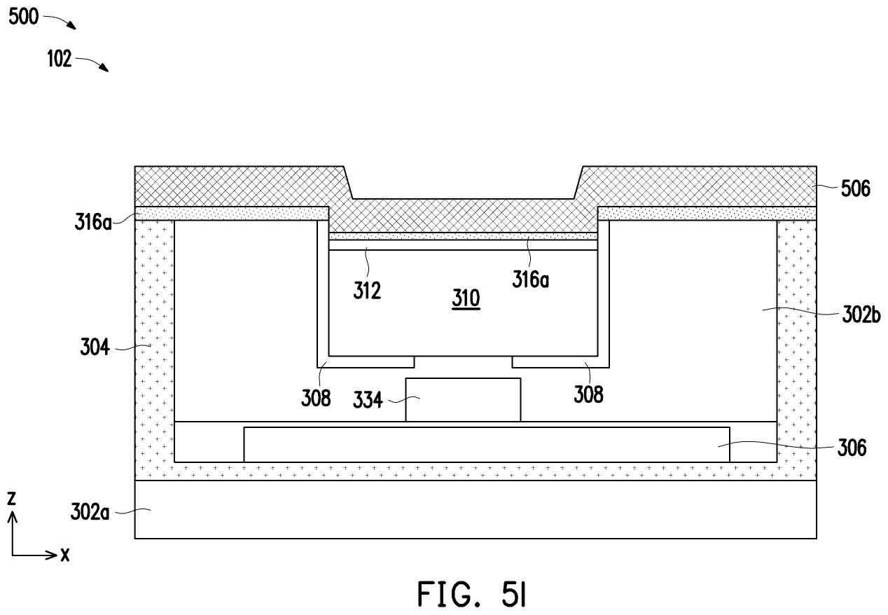

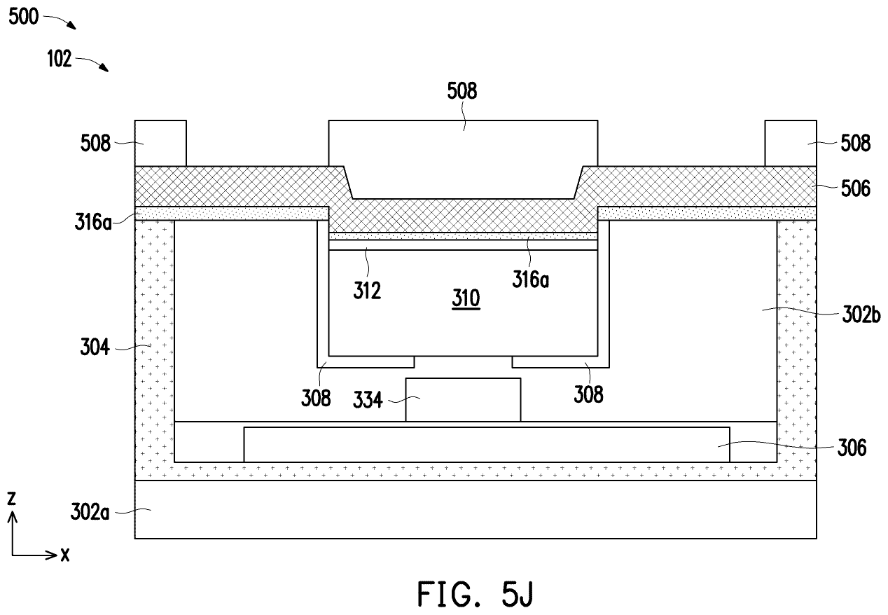

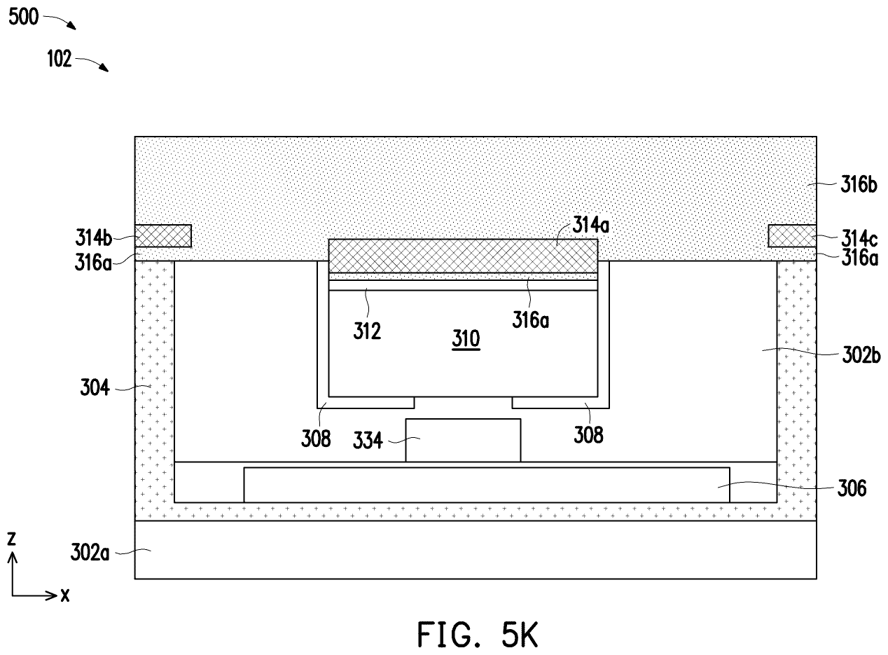

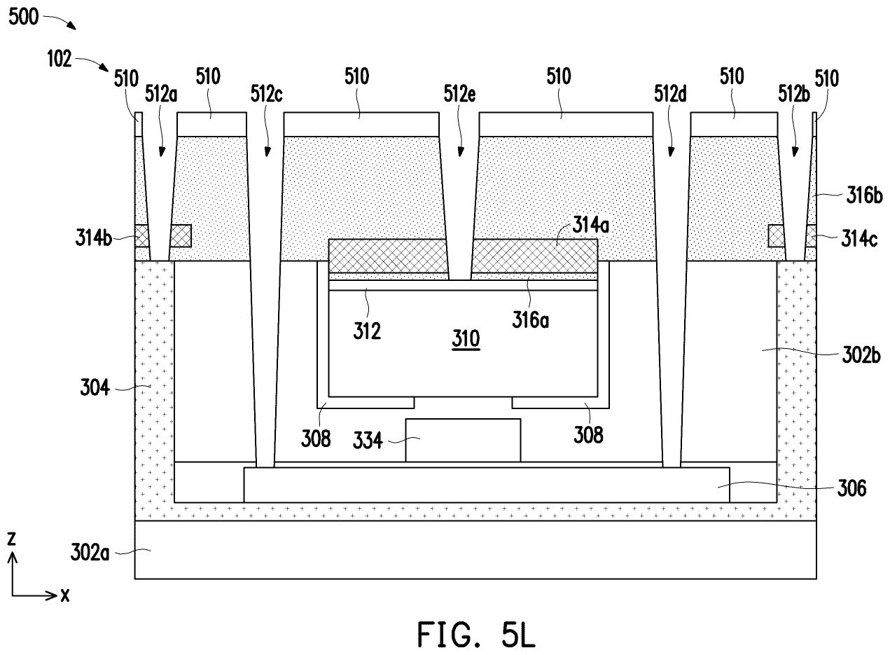

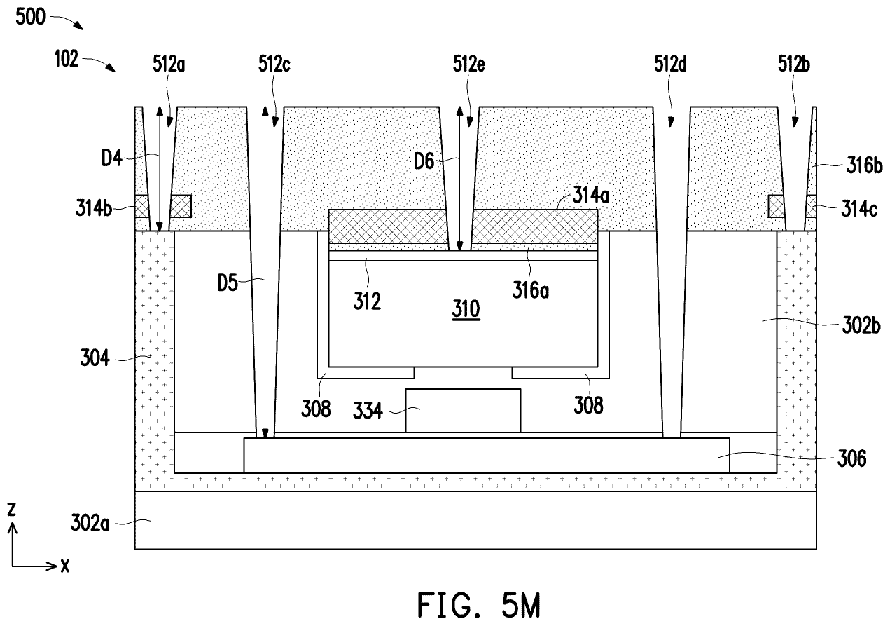

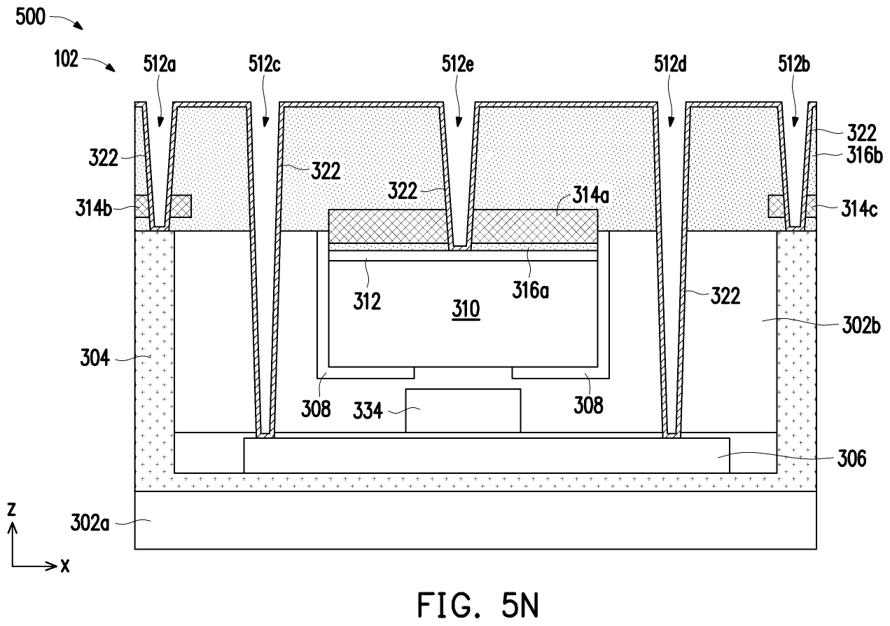

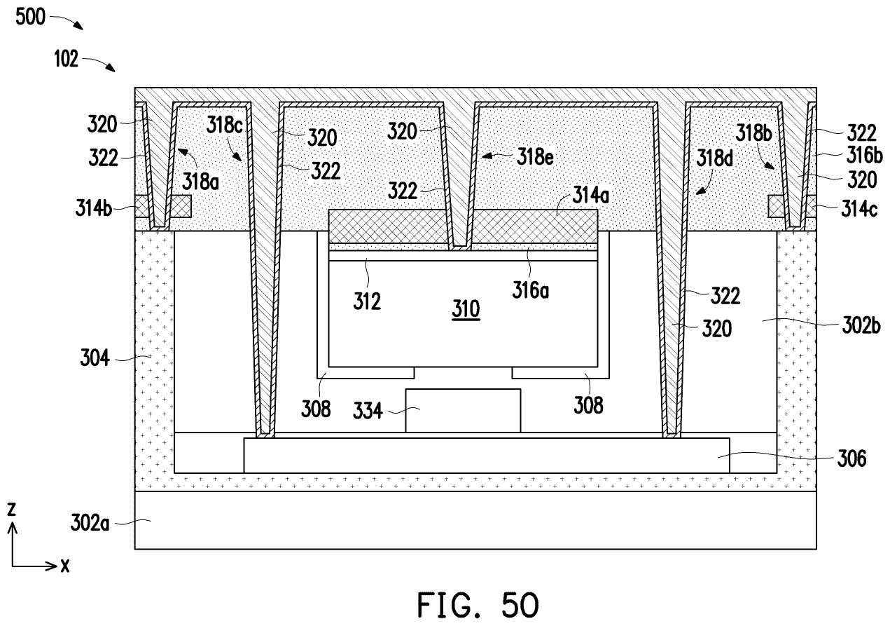

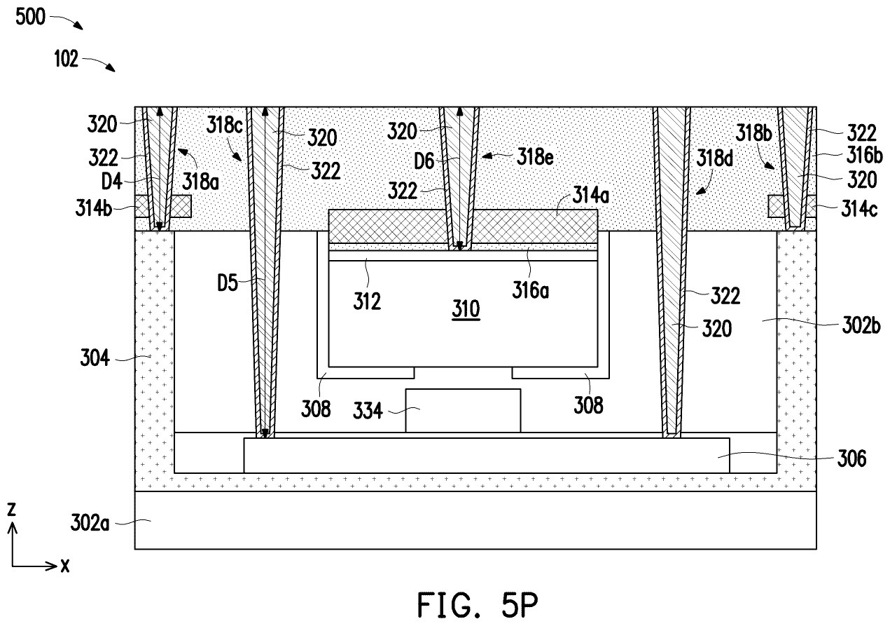

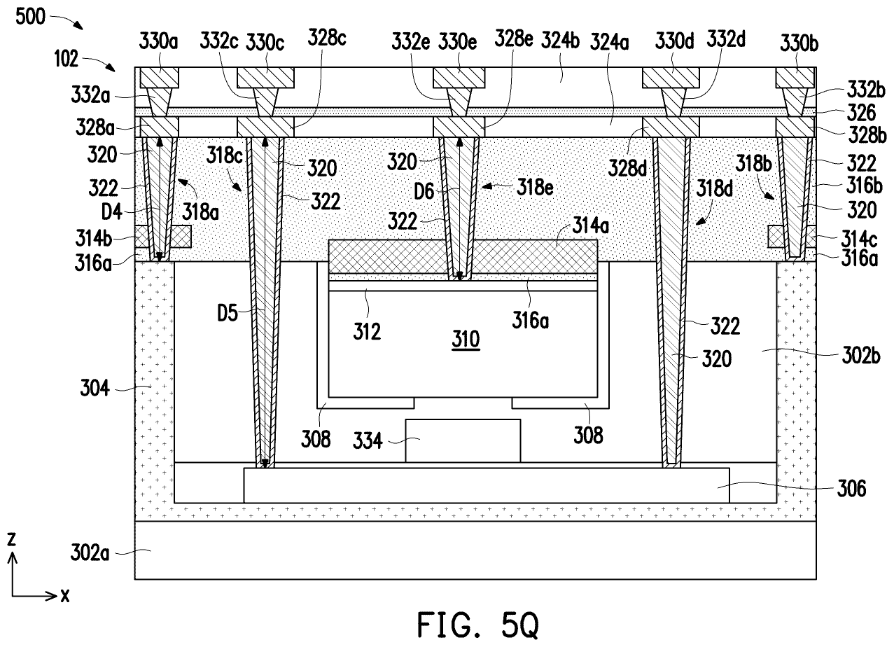

FIGS. 5A-5Q are diagrams of an example implementation 500 of forming a photodetector structure 102 described herein. While the example implementation 500 includes an example of forming the example implementation 300 of the photodetector structure 102 illustrated and described in connection with FIG. 3, the semiconductor processing operations and/or techniques illustrated and described in connection with FIGS. 5A-5Q (or a subset thereof) may be used to manufacture other example implementations of photodetector structures 102 illustrated and described herein. In some implementations, one or more of the semiconductor processing operations described in connection with FIGS. 5A-5Q are performed by one or more semiconductor processing tools and/or a wafer/die transport tool.

Turning to FIG. 5A, a first semiconductor layer 302a in the form of a substrate may be provided. The first semiconductor layer 302a may be provided as a semiconductor wafer, a semiconductor die, and/or another type of semiconductor substrate. In some implementations, the first semiconductor layer 302a may be a doped substrate, such as a semiconductor substrate that is doped with one or more p-type dopants, a semiconductor substrate that is doped with one or more n-type dopants, and/or another type of doped substrate.

As shown in FIG. 5B, one or more types of deposition tools may be used to deposit and/or grow a second semiconductor layer 302b on the first semiconductor layer 302a. For example, a deposition tool may be used to grow the second semiconductor layer 302b by epitaxial growth, which may include epitaxy techniques such as a molecular beam epitaxy (MBE), a metalorganic chemical vapor deposition (MOCVD) process, and/or another suitable epitaxy technique. Additionally and/or alternatively, the second semiconductor layer 302b may be deposited by chemical vapor deposition (CVD), physical vapor deposition (PVD), atomic layer deposition (ALD), and/or another suitable deposition technique.

As shown in FIG. 5C, one or more implantation operations may be performed to form the p-doped region 304 in the first and second semiconductor layers 302a and 302b, the n-doped region 306 in the first semiconductor layer 302a, the p-doped region 334 in the second semiconductor layer 302b. The n-doped region 306 may be formed below the surface of the first semiconductor layer 302a. The p-doped region 304 may be formed at the surface of the second semiconductor layer 302b and extend below the surfaces of the first and second semiconductor layers 302a and 302b. The p-doped region 334 may be formed at a bottom of the second semiconductor layer 302b and may be spaced apart from the n-doped region 306. The n-doped region 306 may in contact with or spaced apart from the p-doped region 304.

In some implementations, an ion implantation tool performs the one or more implantation operations to form the p-doped region 304 in the first and second semiconductor layers 302a and 302b, and the p-doped region 334 in the second semiconductor layer 302b by performing an ion implantation operation to implant ions (e.g., p-type ions) into the first and second semiconductor layers 302a and 302b to form the p-doped region 304 and the p-doped region 334. In some implementations, an ion implantation tool performs the one or more implantation operations to form the n-doped region 306 in the first semiconductor layer 302a by performing an ion implantation operation to implant ions (e.g., n-type ions) into the first semiconductor layer 302a to form the n-doped region 306. The ion implantation tool may direct an ion beam toward the first and second semiconductor layers 302a and 302b such that the ions are implanted below the surfaces of the first and second semiconductor layers 302a and 302b to dope the first and second semiconductor layers 302a and 302b. One or more implantation masks may be formed on the second semiconductor layer 302b, and patterns formed in the one or more implantation masks may be used to form the p-doped region 304, the n-doped region 306, and the p-doped region 334 in the first and second semiconductor layers 302a and 302b in the arrangement shown in FIG. 5C.

As shown in FIG. 5D, based on a pattern in a photoresist layer 502, a portion of the second semiconductor layer 302b may be etched to define a recess 504 in the second semiconductor layer 302b. A deposition tool may be used to form the photoresist layer 502 on the second semiconductor layer 302b. An exposure tool may be used to expose the photoresist layer 502 to a radiation source to pattern the photoresist layer 502. A developer tool may be used to develop and remove portions of the photoresist layer 502 to expose the pattern. An etch tool may be used to etch the second semiconductor layer 302b based on the pattern. In some implementations, the etch operation includes a plasma etch operation, a wet chemical etch operation, and/or another type of etch operation.

In some implementations, as shown in FIG. 5E, a photoresist removal tool may be used to remove the remaining portions of the photoresist layer 502 (e.g., using a chemical stripper, plasma ashing, and/or another technique). In some implementations, a hard mask layer is used as an alternative technique for etching the second semiconductor layer 302b based on a pattern.

As further shown in FIG. 5E, one or more implantation operations may be performed to form the p-doped regions 308 in the second semiconductor layer 302b on sides and a portion of the bottom surface of the recess 504. The p-doped regions 308 may be formed at the surface of the second semiconductor layer 302b and extend below the surface of the second semiconductor layer 302b. The p-doped regions 308 may be spaced apart from the p-doped region 334, the n-doped region 306, and the p-doped region 304.

In some implementations, an ion implantation tool performs the one or more implantation operations to form the p-doped regions 308 in the second semiconductor layer 302b by performing an ion implantation operation to implant ions (e.g., p-type ions) into the second semiconductor layer 302b to form the p-doped regions 308. The ion implantation tool may direct an ion beam toward the second semiconductor layer 302b such that the ions are implanted below the surface of the second semiconductor layer 302b to dope the second semiconductor layer 302b. One or more implantation masks may be formed on the second semiconductor layer 302b, and patterns formed in the one or more implantation masks may be used to form the p-doped regions 308 in the second semiconductor layer 302b in the arrangement shown in FIG. 5E.

As shown in FIGS. 5F and 5G, one or more types of deposition tools may be used to deposit and/or grow the photon absorption region 310 in the recess 504 from the second semiconductor layer 302b, and to grow the buffer layer 312 on the photon absorption region 310 in the recess 504. For example, a deposition tool may be used to grow the photon absorption region 310 and/or the buffer layer 312 by epitaxial growth, which may include epitaxy techniques such as an MBE, an MOCVD process, and/or another suitable epitaxy technique. Additionally and/or alternatively, the photon absorption region 310 and/or the buffer layer 312 may be deposited by CVD, PVD, ALD, and/or another suitable deposition technique.

As shown in FIG. 5H, the first dielectric layer 316a is deposited on the buffer layer 312 in the recess 504, and on top surfaces of second semiconductor layer 302b. In some implementations, the first dielectric layer 316a may be deposited by a CVD, PVD, ALD, and/or another suitable deposition technique.

As shown in FIG. 5I, a blanket ESL 506 is deposited on the first dielectric layer 316a in the recess 504, and on top surfaces of second semiconductor layer 302b. The blanket ESL 506 fills in a remaining portion of the recess 504, and a portion of the blanket ESL 506 is outside of the recess 504. In some implementations, the blanket ESL 506 may be deposited by a CVD, PVD, ALD, and/or another suitable deposition technique.

As shown in FIGS. 5J and 5K, the blanket ESL 506 may be etched to pattern the blanket ESL 506 into the first ESL 314a, the second ESL 314b, and the third ESL 314c. In some implementations, a pattern in a photoresist layer 508 is used to define the regions of the blanket ESL 506 to be etched. In these implementations, a deposition tool may be used to form the photoresist layer 508 on the blanket ESL 506. An exposure tool may be used to expose the photoresist layer 508 to a radiation source to pattern the photoresist layer 508. A developer tool may be used to develop and remove portions of the photoresist layer 508 to expose the pattern. An etch tool may be used to etch the blanket ESL 506 based on the pattern. In some implementations, the etch operation includes a plasma etch operation, a wet chemical etch operation, and/or another type of etch operation. In some implementations, a photoresist removal tool may be used to remove the remaining portions of the photoresist layer 508 (e.g., using a chemical stripper, plasma ashing, and/or another technique). In some implementations, a hard mask layer is used as an alternative technique for etching the blanket ESL 506 to form the first ESL 314a, the second ESL 314b, and the third ESL 314c based on a pattern.

As further shown in FIG. 5K, a bottom portion of the first ESL 314a is formed in the recess 504, and a top portion of the first ESL 314a extends out of the recess 504. The second and third ESLs 314b and 314c are formed on portions of the first dielectric layer 316a over the top surfaces of the p-doped region 304 on opposite lateral sides of the photodetector structure 102 in the x-direction.

Following removal of the remaining portions of the photoresist layer 508, the second dielectric layer 316b is deposited on the first dielectric layer 316a, and on and around the first ESL 314a, the second ESL 314b, and the third ESL 314c. The second dielectric layer 316b may be deposited by a CVD, PVD, ALD, and/or another suitable deposition technique, which may be followed by a planarization process (e.g., a chemical mechanical planarization (CMP) process).

As shown in FIG. 5L, a dielectric masking layer 510 may be formed on the second dielectric layer 316b. The dielectric masking layer 510 may include a silicon oxynitride material (SiON) and/or another suitable dielectric material. A deposition tool may be used to deposit the dielectric masking layer 510 using a PVD technique, an ALD technique, a CVD technique, an oxidation technique, and/or another suitable deposition technique. In some implementations, a planarization tool is used to perform a planarization operation (e.g., a CMP operation) to planarize the dielectric masking layer 510 after the dielectric masking layer 510 is deposited.

A photoresist layer may be formed above the dielectric masking layer 510, and a pattern may be formed in the photoresist layer. A deposition tool may be used to form the photoresist layer on the dielectric masking layer 510 (e.g., using a spin-coating technique or another suitable deposition technique). In some implementations, a BARC is first deposited on the dielectric masking layer 510, and then the photoresist layer is deposited onto the BARC. An exposure tool may be used to expose the photoresist layer to a radiation source to pattern the photoresist layer. A developer tool may be used to develop and remove portions of the photoresist layer to expose the pattern.

An etch tool may be used to etch the dielectric masking layer 510 based on the pattern in the photoresist layer, to transfer the pattern to the dielectric masking layer 510. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique).

Another etch operation may be performed to etch through portions of the first and second dielectric layers 316a and 316b, portions of the ESLs 314a-314c, and/or portions of the first and second semiconductor layers 302a and 302b to form recesses 512a, 512b, 512c, 512d, and 512e. The recesses 512a and 512b are respectively formed through the first and second dielectric layers 316a and 316b, and through the second and third ESLs 314b and 314c. Bottom surfaces of the recesses 512a and 512b expose portions of the top surfaces of the p-doped region 304. The recesses 512c and 512d are respectively formed through the first and second dielectric layers 316a and 316b, through the second semiconductor layer 302b, and in the first semiconductor layer 302a. Bottom surfaces of the recesses 512c and 512d expose portions of the top surfaces of the n-doped region 306. The recess 512e is formed through the first and second dielectric layers 316a and 316b, and through the first ESL 314a. A bottom surface of the recess 512e exposes a portion of the top surface of the buffer layer 312. The etch operation may include, for example, a gas-based etch operation in which a different type of etchant is used, as compared to the etchant that was used to transfer the pattern to the dielectric masking layer 510. Thus, the semiconductor device 100 may be transferred from a first etch tool (in which the pattern was transferred to the dielectric masking layer 510) to a second etch tool (in which the first and second dielectric layers 316a and 316b, the ESLs 314a-314c, and/or the first and second semiconductor layers 302a and 302b are etched) using a wafer/die transport tool to reduce the likelihood of cross-contamination between the first and second etch tools. Alternatively, an etch tool that has multiple processing chambers (e.g., a cluster tool) may be used, and the semiconductor device 100 may be transferred between processing chambers of the etch tool for etching using different types of etchants.

As shown in FIG. 5M, the dielectric masking layer 510 may be removed. In some implementations, a vertical dimension D4 in the z-direction of the recesses 512a and 512b may be the same as that of the contact structures 318a and 318b, and is smaller than a vertical dimension D5 in the z-direction of the recesses 512c and 512d. The vertical dimension D5 in the z-direction of the recesses 512c and 512d may be the same as that of contact structures 318c and 318d. The vertical dimension D4 in the z-direction of the recesses 512a and 512b is smaller than a vertical dimension D6 in the z-direction of the recess 512e. The vertical dimension D6 in the z-direction of the recess 512e may be the same as that of the contact structure 318e. The vertical dimension D5 in the z-direction of the recesses 512c and 512d is greater than the vertical dimensions D4 and D6.

The recesses 512a-512e are formed in a same etch operation by using the same mask structure (e.g., dielectric masking layer 510), where the same etch operation includes applying an etchant (e.g., a gas-based etchant) to the photodetector structure 102 to etch different portions of the first and second dielectric layers 316a and 316b and underlying layers to form the recesses 512a-512e based on a pattern in the dielectric masking layer 510. The ESLs 314a-314c slow down etching of the recesses 512a, 512b, and 512e with smaller vertical dimensions D4 and D6 than the vertical dimension D5 of the recesses 512c and 512d. The etch rates of the ESLs 314a-314c are slower than the etch rates of the first and second dielectric layers 316a and 316b, and slower than the etch rates of the first and second semiconductor layers 302a and 302b. As a result, the etching of recesses 512a-512e for the contact structures 318a-318e with different vertical dimensions D4-D6 may be performed in the same etch operation, where the etching of the recesses 512a-512e with the different vertical dimensions D4-D6 is completed at the same or approximately the same time. The vertical dimension in the z-direction (e.g., thickness) of the ESLs 314a-314c may be controlled to ensure that etching of the recesses 512a-512e with the different vertical dimensions D4-D6 is completed at the same or approximately the same time.

As shown in FIG. 5N, the liner layer 322 may be deposited on the sidewalls and on the bottom surfaces of the recesses 512a-512e. The bottom surfaces of the recesses 512a and 512b correspond to the top surfaces of the p-doped region 304, the bottom surfaces of the recesses 512c and 512d correspond to the top surface of the n-doped region 306, and the bottom surface of the recess 512e corresponds to the top surface of the buffer layer 312. Thus, the liner layer 322 may be in physical contact with the top surfaces of the p-doped region 304, n-doped region 306, and buffer layer 312. The liner layer 322 may also be deposited on the top surface of the second dielectric layer 316a between adjacent recesses 512. In some implementations, a deposition tool is used to conformally deposit the liner layer 322 such that the liner layer 322 conforms to the profile of the recesses 512a-512e. In some implementations, a conformal CVD technique and/or an ALD technique is used to deposit the liner layer 322.

As shown in FIG. 5O, the fill layer 320 may be deposited on the liner layer 322. The fill layer 320 may be deposited such that the fill layer 320 fills the remaining areas of the recesses 512a-512e. The fill layer 320 may also be deposited on the top surface of the liner layer 322 between recesses 512. As shown in FIG. 5P, the fill layer 320 and the liner layer 322 are removed from the top surface of the second dielectric layer 316b in a subsequent CMP operation. In some implementations, a deposition tool is used to deposit the fill layer 320 using a PVD technique, a CVD technique, an ALD technique, and/or another suitable deposition technique to form the contact structures 318a-318e including the fill layers 320 and the liner layers 322.

As shown in FIG. 5Q, the interconnect layer including the ILD layers 324a and 324b, and the interconnect layer ESL 326, is formed over the second dielectric layer 316b and the contact structures 318a-318e. One or more deposition tools are used to deposit alternating layers of ILD layers 324a and 324b, and the interconnect layer ESL 326. In this way, the ILD layers 324a and 324b and the interconnect layer ESL 326 may be arranged in the z-direction in the semiconductor device 100. One or more deposition tools may be used to deposit each of the ILD layers 324a and 324b and the interconnect layer ESL 326 using a PVD technique, an ALD technique, a CVD technique, an oxidation technique, and/or another suitable deposition technique. In some implementations, a planarization tool may be used to planarize the ILD layers 324a and 324b and/or the interconnect layer ESL 326 after the ILD layers 324a and 324b and/or the interconnect layer ESL 326 are deposited.

As further shown in FIG. 5Q, a deposition tool, an exposure tool, a developer tool, an etch tool, a planarization tool, a plating tool, and/or another semiconductor processing tool may be used to perform various operations to form the metallization structures 328a-328e and 330a-330e, and to form the interconnect structures 332a-332e.

One or more deposition tools may be used to deposit the metallization structures 328a-328e and 330a-330e and/or the interconnect structures 332a-332e using a PVD technique, an ALD technique, a CVD technique, an electroplating technique (e.g., an electro-chemical plating technique), and/or another suitable deposition technique. In some implementations, a planarization tool may be used to planarize the metallization structures 328a-328e and 330a-330e and/or the interconnect structures 332a-332e after the metallization structures 328a-328e and 330a-330e and/or the interconnect structures 332a-332e are deposited.

As indicated above, FIGS. 5A-5Q are provided as an example. Other examples may differ from what is described with regard to FIGS. 5A-5Q.

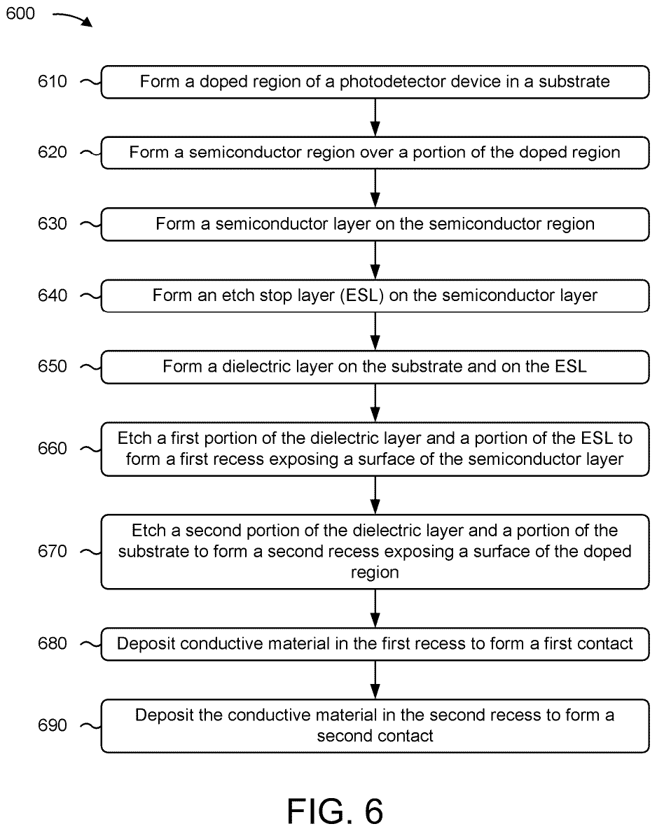

FIG. 6 is a flowchart of an example process 600 associated with a method of forming a semiconductor device. In some implementations, one or more process blocks of FIG. 6 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 6, process 600 may include forming a doped region of a photodetector device in a substrate (block 610). For example, one or more semiconductor processing tools may be used to form a doped region (e.g., n-doped region 206, 306) of a photodetector device (e.g., photodetector structure 102) in a substrate (e.g., semiconductor layer 202, first semiconductor layer 302a), as described herein.

As further shown in FIG. 6, process 600 may include forming a semiconductor region over a portion of the doped region (block 620). For example, one or more semiconductor processing tools may be used to form a semiconductor region (e.g., photon absorption region 210, 310) over a portion of the doped region, as described herein.

As further shown in FIG. 6, process 600 may include forming a semiconductor layer on the semiconductor region (block 630). For example, one or more semiconductor processing tools may be used to form a semiconductor layer (e.g., first buffer layer 212a, buffer layer 312) on the semiconductor region, as described herein.

As further shown in FIG. 6, process 600 may include forming an etch stop layer (ESL) on the semiconductor layer (block 640). For example, one or more semiconductor processing tools may be used to form an etch stop layer (ESL) (e.g., first ESL 214a, 314a) on the semiconductor layer, as described herein.

As further shown in FIG. 6, process 600 may include forming a dielectric layer on the substrate and on the ESL (block 650). For example, one or more semiconductor processing tools may be used to form a dielectric layer (e.g., dielectric layer 216, second dielectric layer 316b) on the substrate and on the ESL, as described herein.

As further shown in FIG. 6, process 600 may include etching a first portion of the dielectric layer and a portion of the ESL to form a first recess exposing a surface of the semiconductor layer (block 660). For example, one or more semiconductor processing tools may be used to etch a first portion of the dielectric layer and a portion of the ESL to form a first recess (e.g., recess 406e, 406f, 512e) exposing a surface of the semiconductor layer, as described herein.

As further shown in FIG. 6, process 600 may include etching a second portion of the dielectric layer and a portion of the substrate to form a second recess exposing a surface of the doped region (block 670). For example, one or more semiconductor processing tools may be used to etch a second portion of the dielectric layer and a portion of the substrate to form a second recess (e.g., recess 406c, 406d, 512c, 512d) exposing a surface of the doped region, as described herein. In some implementations, etching to form the first recess and etching to form the second recess are performed during a same etch operation. In some implementations, an etch rate of the dielectric layer is faster than an etch rate of the ESL.

As further shown in FIG. 6, process 600 may include depositing conductive material in the first recess to form a first contact (block 680). For example, one or more semiconductor processing tools may be used to deposit conductive material (e.g., fill layer 220, 320, liner layer 222, 322) in the first recess to form a first contact (contact structure 218e, 218f, 318e), as described herein.

As further shown in FIG. 6, process 600 may include depositing the conductive material in the second recess to form a second contact (block 690). For example, one or more semiconductor processing tools may be used to deposit the conductive material in the second recess to form a second contact (e.g., contact structure 218c, 218d, 318c, 318d), as described herein.

Process 600 may include additional implementations, such as any single implementation or any combination of implementations described below and/or in connection with one or more other processes described elsewhere herein.

In a first implementation, a vertical dimension (e.g., vertical dimension D3, D6) of the first recess is smaller than a vertical dimension (e.g., vertical dimension D2, D5) of the second recess.

In a second implementation, alone or in combination with the first implementation, an etch rate of the substrate is faster than the etch rate of the ESL.

In a third implementation, alone or in combination with one or more of the first and second implementations, process 600 includes forming an additional doped region (e.g., p-doped region 204, 304) in the substrate, forming an additional ESL (e.g., second ESL 214b, 314b) over the additional doped region, and etching a third portion of the dielectric layer and a portion of the additional ESL to form a third recess (e.g., recess 406a, 406b, 512a, 512b) exposing a surface of the additional doped region, where etching to form the third recess is performed during the same etch operation as etching to form the first recess and etching to form the second recess.

In a fourth implementation, alone or in combination with one or more of the first through third implementations, an etch rate of the dielectric layer is faster than an etch rate of the additional ESL.

In a fifth implementation, alone or in combination with one or more of the first through fourth implementations, an etch rate of the substrate is faster than an etch rate of the additional ESL.

In a sixth implementation, alone or in combination with one or more of the first through fifth implementations, a vertical dimension (e.g., vertical dimension D1, D4) of the third recess is smaller than a vertical dimension (e.g., vertical dimension D2, D5) of the second recess.

In a seventh implementation, alone or in combination with one or more of the first through sixth implementations, a vertical dimension (e.g., vertical dimension D1) of the third recess is larger than a vertical dimension (e.g., vertical dimension D3) of the first recess.

In an eighth implementation, alone or in combination with one or more of the first through seventh implementations, a vertical dimension (e.g., vertical dimension D4) of the third recess is smaller than a vertical dimension (e.g., vertical dimension D6) of the first recess.

In a ninth implementation, alone or in combination with one or more of the first through eighth implementations, the semiconductor region (210) is formed on the substrate.

In a tenth implementation, alone or in combination with one or more of the first through ninth implementations, an additional semiconductor layer (e.g., second semiconductor layer 302b) is formed on the substrate, and the semiconductor region (e.g., photon absorption region 310) and the semiconductor layer (e.g., buffer layer 312) are formed in the additional semiconductor layer.

Although FIG. 6 shows example blocks of process 600, in some implementations, process 600 includes additional blocks, fewer blocks, different blocks, or differently arranged blocks than those depicted in FIG. 6. Additionally, or alternatively, two or more of the blocks of process 600 may be performed in parallel.

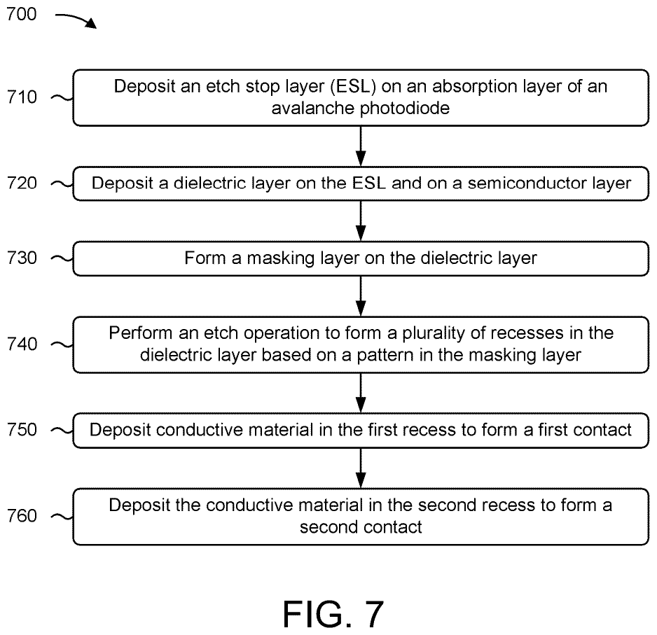

FIG. 7 is a flowchart of an example process 700 associated with a method of forming a semiconductor device. In some implementations, one or more process blocks of FIG. 7 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 7, process 700 may include depositing an etch stop layer (ESL) on an absorption layer of an avalanche photodiode (block 710). For example, one or more semiconductor processing tools may be used to deposit an etch stop layer (ESL) (e.g., first ESL 214a, 314a) on an absorption layer (e.g., photon absorption region 210, 310) of an avalanche photodiode, as described herein.

As further shown in FIG. 7, process 700 may include depositing a dielectric layer on the ESL and on a semiconductor layer (block 720). For example, one or more semiconductor processing tools may be used to deposit a dielectric layer (e.g., dielectric layer 216, e.g., second dielectric layer 316 b) on the ESL and on a semiconductor layer (e.g., semiconductor layer 202, second semiconductor layer 302b), as described herein.

As further shown in FIG. 7, process 700 may include forming a masking layer on the dielectric layer (block 730). For example, one or more semiconductor processing tools may be used to form a masking layer (e.g., dielectric masking layer 404, 510) on the dielectric layer, as described herein.

As further shown in FIG. 7, process 700 may include performing an etch operation to form a plurality of recesses the dielectric layer based on a pattern in the masking layer (block 740). For example, one or more semiconductor processing tools may be used to perform an etch operation to form a plurality of recesses (e.g., recesses 406, 512) in the dielectric layer based on a pattern in the masking layer, as described herein. In some implementations, performing the etch operation includes etching a first portion of the dielectric layer and an underlying portion of the ESL to form a first recess (e.g., recess 406e, 406f, 512e) of the plurality of recesses over the absorption layer, and etching a second portion of the dielectric layer and an underlying portion of the semiconductor layer to form a second recess (e.g., recess 406c, 406d, 512c, 512d) of the plurality of recesses over a doped region (e.g., n-doped region 206, 306). In some implementations, the doped region is formed under the absorption layer. In some implementations, an etch rate of the ESL is slower than an etch rate of the dielectric layer and an etch rate of the semiconductor layer.

As further shown in FIG. 7, process 700 may include depositing conductive material in the first recess to form a first contact (block 750). For example, one or more semiconductor processing tools may be used to deposit conductive material (e.g., fill layer 220, 320, liner layer 222, 322) in the first recess to form a first contact (e.g., contact structure 218e, 218f, 318e), as described herein.

As further shown in FIG. 7, process 700 may include depositing the conductive material in the second recess to form a second contact (block 760). For example, one or more semiconductor processing tools may be used to deposit the conductive material in the second recess to form a second contact (e.g., contact structure 218c, 218d, 318c, 318d), as described herein.

Process 700 may include additional implementations, such as any single implementation or any combination of implementations described below and/or in connection with one or more other processes described elsewhere herein.

In a first implementation, process 700 includes etching parts of the ESL and the absorption layer to reduce a lateral width of the ESL and the absorption layer prior to depositing the dielectric layer.

In a second implementation, alone or in combination with the first implementation, the absorption layer is formed in a recess (e.g., recess 504) in the semiconductor layer, and a portion of the ESL is deposited in the recess.

In a third implementation, alone or in combination with one or more of the first and second implementations, the doped region is formed in an additional semiconductor layer (e.g., first semiconductor layer 302a) disposed under the semiconductor layer, where the second recess is formed through a portion of the additional semiconductor layer.

In a fourth implementation, alone or in combination with one or more of the first through third implementations, an additional doped region (e.g., p-doped region 204, 304) is formed around the doped region, where performing the etch operation further includes etching a third portion of the dielectric layer and an underlying portion of an additional ESL (e.g., second ESL 214b, 314b) to form a third recess of the plurality of recesses over the additional doped region, and where a doping type of the additional doped region is different from a doping type of the doped region.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

In this way, ESLs are formed on an absorption layer and on doped regions of a SPAD before etching recesses for contact structures that are to be formed over the absorption layer and the doped regions. The etch rate for the ESLs is slower than etch rates for other materials in which the recesses will be formed so that one contact mask and one etch process can be used to form shallow and deep contact structures. In more detail, the ESLs reduce the etch rate when forming recesses with smaller vertical dimensions in comparison to the etch rate when forming recesses with larger vertical dimensions. As a result, the etching of contact structure recesses with larger and smaller vertical dimensions may be performed in the same etch operation, where the etching of the recesses with the different vertical dimensions is completed at the same or approximately the same time. Thicknesses of the ESLs may be controlled so that etching of recesses having the different vertical dimensions is simultaneously completed. The use of a single mask (e.g., photoresist) in an etch operation to form contact structure recesses with the different vertical dimensions prevents unwanted residue that may be formed on dielectric layers and/or in recesses from multiple masks. As a result, device performance and/or reliability may be increased. In addition, difficulties in aligning a metallization layer with shallow and deep contact structures that may be encountered when multiple recess etch operations are performed may be avoided.

As described in greater detail above, some implementations described herein provide a method. The method includes forming a doped region of a photodetector device in a substrate. The method includes forming a semiconductor region over a portion of the doped region. The method includes forming a semiconductor layer on the semiconductor region. The method includes forming an etch stop layer (ESL) on the semiconductor layer. The method includes forming a dielectric layer on the substrate and on the ESL. The method includes etching a first portion of the dielectric layer and a portion of the ESL to form a first recess exposing a surface of the semiconductor layer. The method includes etching a second portion of the dielectric layer and a portion of the substrate to form a second recess exposing a surface of the doped region, where etching to form the first recess and etching to form the second recess are performed during a same etch operation, and where an etch rate of the dielectric layer is faster than an etch rate of the ESL. The method includes depositing conductive material in the first recess to form a first contact. The method includes depositing the conductive material in the second recess to form a second contact.

As described in greater detail above, some implementations described herein provide a method. The method includes depositing an etch stop layer (ESL) on an absorption layer of an avalanche photodiode. The method includes depositing a dielectric layer on the ESL and on a semiconductor layer. The method includes forming a masking layer on the dielectric layer. The method includes performing an etch operation to form a plurality of recesses in the dielectric layer based on a pattern in the masking layer, where performing the etch operation includes etching a first portion of the dielectric layer and an underlying portion of the ESL to form a first recess of the plurality of recesses over the absorption layer, and etching a second portion of the dielectric layer and an underlying portion of the semiconductor layer to form a second recess of the plurality of recesses over a doped region, where the doped region is formed under the absorption layer, and where an etch rate of the ESL is slower than an etch rate of the dielectric layer and an etch rate of the semiconductor layer. The method includes depositing conductive material in the first recess to form a first contact. The method includes depositing the conductive material in the second recess to form a second contact.

As described in greater detail above, some implementations described herein provide a semiconductor structure. The semiconductor structure includes a semiconductor region disposed on a first doped region. The semiconductor structure includes a first etch stop layer (ESL) disposed on the semiconductor region. The semiconductor structure includes a first contact structure disposed through the first ESL and over the semiconductor region. The semiconductor structure includes a second doped region disposed in a semiconductor layer, where the second doped region is disposed under the semiconductor region and the first doped region. The semiconductor structure includes a second contact structure disposed in the semiconductor layer and over the second doped region. The semiconductor structure includes a third doped region disposed in the semiconductor layer adjacent to the second doped region. The semiconductor structure includes a second ESL disposed on the third doped region. The semiconductor structure includes a third contact structure disposed through the second ESL and over the third doped region.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a doped region of a photodetector device in a substrate;
forming a semiconductor region over a portion of the doped region;
forming a semiconductor layer on the semiconductor region;
forming an etch stop layer (ESL) on the semiconductor layer;
forming a dielectric layer on the substrate and on the ESL;
etching a first portion of the dielectric layer and a portion of the ESL to form a first recess exposing a surface of the semiconductor layer;
etching a second portion of the dielectric layer and a portion of the substrate to form a second recess exposing a surface of the doped region,
wherein etching to form the first recess and etching to form the second recess are performed during a same etch operation, and
wherein an etch rate of the dielectric layer is faster than an etch rate of the ESL;
depositing conductive material in the first recess to form a first contact; and
depositing the conductive material in the second recess to form a second contact.

2. The method of claim 1, wherein a vertical dimension of the first recess is smaller than a vertical dimension of the second recess.

3. The method of claim 1, wherein an etch rate of the substrate is faster than the etch rate of the ESL.

4. The method of claim 1, further comprising:
forming an additional doped region in the substrate;
forming an additional ESL over the additional doped region; and
etching a third portion of the dielectric layer and a portion of the additional ESL to form a third recess exposing a surface of the additional doped region,
wherein etching to form the third recess is performed during the same etch operation as etching to form the first recess and etching to form the second recess.

5. The method of claim 4, wherein an etch rate of the dielectric layer is faster than an etch rate of the additional ESL.

6. The method of claim 4, wherein an etch rate of the substrate is faster than an etch rate of the additional ESL.

7. The method of claim 4, wherein a vertical dimension of the third recess is smaller than a vertical dimension of the second recess.

8. The method of claim 4, wherein a vertical dimension of the third recess is larger than a vertical dimension of the first recess.

9. The method of claim 4, wherein a vertical dimension of the third recess is smaller than a vertical dimension of the first recess.

10. The method of claim 1, wherein the semiconductor region is formed on the substrate.

11. The method of claim 1, wherein an additional semiconductor layer is formed on the substrate, and
wherein the semiconductor region and the semiconductor layer are formed in the additional semiconductor layer.

12. A method, comprising:
depositing an etch stop layer (ESL) on an absorption layer of an avalanche photodiode;
depositing a dielectric layer on the ESL and on a semiconductor layer;
forming a masking layer on the dielectric layer;
performing an etch operation to form a plurality of recesses in the dielectric layer based on a pattern in the masking layer,
wherein performing the etch operation comprises:
etching a first portion of the dielectric layer and an underlying portion of the ESL to form a first recess of the plurality of recesses over the absorption layer; and
etching a second portion of the dielectric layer and an underlying portion of the semiconductor layer to form a second recess of the plurality of recesses over a doped region,
wherein the doped region is formed under the absorption layer, and
wherein an etch rate of the ESL is slower than an etch rate of the dielectric layer and an etch rate of the semiconductor layer;
depositing conductive material in the first recess to form a first contact; and
depositing the conductive material in the second recess to form a second contact.

13. The method of claim 12, further comprising etching parts of the ESL and the absorption layer to reduce a lateral width of the ESL and the absorption layer prior to depositing the dielectric layer.

14. The method of claim 12, wherein the absorption layer is formed in a recess in the semiconductor layer, and
wherein a portion of the ESL is deposited in the recess.

15. The method of claim 12, wherein the doped region is formed in an additional semiconductor layer disposed under the semiconductor layer, and
wherein the second recess is formed through a portion of the additional semiconductor layer.

16. The method of claim 12, wherein an additional doped region is formed around the doped region,
wherein performing the etch operation further comprises etching a third portion of the dielectric layer and an underlying portion of an additional ESL to form a third recess of the plurality of recesses over the additional doped region, and
wherein a doping type of the additional doped region is different from a doping type of the doped region.

17. A semiconductor structure, comprising:
a semiconductor region disposed on a first doped region;
a first etch stop layer (ESL) disposed on the semiconductor region;
a first contact structure disposed through the first ESL and over the semiconductor region;
a second doped region disposed in a semiconductor layer,
wherein the second doped region is disposed under the semiconductor region and the first doped region;
a second contact structure disposed in the semiconductor layer and over the second doped region;
a third doped region disposed in the semiconductor layer adjacent to the second doped region;
a second ESL disposed on the third doped region; and
a third contact structure disposed through the second ESL and over the third doped region.

18. The semiconductor structure of claim 17, further comprising a dielectric layer disposed over the semiconductor region and over the semiconductor layer,
wherein the first contact structure, the second contact structure, and the third contact structure are disposed in the dielectric layer,
wherein the first ESL and the second ESL comprise a first dielectric material, and
wherein the dielectric layer comprises a second dielectric material different from the first dielectric material.

19. The semiconductor structure of claim 17, wherein a vertical dimension of the first contact structure is smaller than a vertical dimension of the second contact structure, and
wherein a vertical dimension of the third contact structure is smaller than a vertical dimension of the second contact structure.

20. The semiconductor structure of claim 17, further comprising a buffer layer disposed between the semiconductor region and the first ESL,
wherein the first contact structure is in contact with the buffer layer.
